(19) United States
(12) Patent Application Publication
(10) Pub. No.: US 2026/0213724 A1
(43) Pub. Date: Jul. 23, 2026

(54) PIEZOELECTRIC DEVICE AND FILTER

(71) Applicant: Murata Manufacturing Co., Ltd., Nagaokakyo-shi (JP)

(72) Inventor: Masashi OMURA, Nagaokakyo-shi (JP)

(21) Appl. No.: 19/572,019

(22) Filed: Mar. 19, 2026

Related U.S. Application Data
(63) Continuation of application No. PCT/JP2024/037057, filed on Oct. 17, 2024.

(30) Foreign Application Priority Data
Oct. 17, 2023 (JP) 2023-178986
May 13, 2024 (JP) 2024-078197

(51) Int. Cl. H03H 9/02; H03H 9/54

(52) U.S. Cl. CPC H03H 9/02015; H03H 9/02157; H03H 9/54

(57) ABSTRACT

A piezoelectric device includes a support including a support substrate, a piezoelectric layer having a thickness in a first direction and provided on a main surface of the support, and a functional electrode provided on a main surface of the piezoelectric layer. The piezoelectric layer includes first and second piezoelectric films stacked on each other. The polarization directions of the first and second piezoelectric films intersect each other. A displacement direction of a main wave of the first piezoelectric film and the displacement direction of a main wave of the second piezoelectric film are parallel directions.

### CROSS REFERENCE TO RELATED APPLICATIONS

This application claims the benefit of priority to Japanese Patent Application No. 2023-178986 filed on Oct. 17, 2023 and Japanese Patent Application No. 2024-078197 filed on May 13, 2024, and is a Continuation Application of PCT Application No. PCT/JP2024/037057 filed on Oct. 17, 2024. The entire contents of each application are hereby incorporated herein by reference.

### BACKGROUND OF THE INVENTION

### 1. Field of the Invention

The present invention relates to piezoelectric devices and filters.

### 2. Description of the Related Art

Japanese Unexamined Patent Application Publication No. 10-51262 discloses a piezoelectric vibrator that includes two piezoelectric single crystal plates and drive electrodes. The two piezoelectric single crystal plates each have a spontaneous polarization and are integrated by being directly bonded to each other so that the axial directions of the spontaneous polarizations are oriented in substantially opposite directions and the other crystal axes are offset from each other by a certain angle that does not include 0°. The drive electrodes are formed opposite each other on two main surfaces of the directly bonded piezoelectric single crystal plates.

### SUMMARY OF THE INVENTION

When a thin film piezoelectric resonance device disclosed in Japanese Unexamined Patent Application Publication No. 10-51262 is used as a filter, spurious waves near a resonance point may occur in the vicinity of the passband. The piezoelectric layer of the thin film piezoelectric resonance device disclosed in Japanese Unexamined Patent Application Publication No. 10-51262 might not be able to sufficiently suppress the spurious waves near the resonance point.

Example embodiments of the present invention provide piezoelectric devices and filters that suppress spurious waves near a resonance point.

According to an example embodiment of the present invention, a piezoelectric device includes a support, a piezoelectric layer, and a functional electrode. The support includes a support substrate. The piezoelectric layer has a thickness in a first direction and is provided on a main surface of the support. The functional electrode is provided on a main surface of the piezoelectric layer. The piezoelectric layer includes a first piezoelectric film and a second piezoelectric film stacked on the first piezoelectric film. A polarization direction of the first piezoelectric film and a polarization direction of the second piezoelectric film are directions that intersect each other. A displacement direction of the first piezoelectric film and a displacement direction of the second piezoelectric film are directions that are parallel to each other.

According to another example embodiment of the present invention, a piezoelectric device includes a support, a piezoelectric layer, and a functional electrode. The support includes a support substrate. The piezoelectric layer has a thickness in a first direction and is provided on a main surface of the support. The functional electrode is provided on a main surface of the piezoelectric layer. The piezoelectric layer includes a first piezoelectric film and a second piezoelectric film stacked on the first piezoelectric film. A polarization direction of the first piezoelectric film and a polarization direction of the second piezoelectric film are directions other than opposite directions. A displacement direction of a main wave of the first piezoelectric film and a displacement direction of a main wave of the second piezoelectric film are opposite directions. A displacement direction of a spurious wave of the first piezoelectric film and a displacement direction of a spurious wave of the second piezoelectric film are identical directions.

According to another example embodiment of the present invention, a piezoelectric device includes a support, a piezoelectric layer, and a functional electrode. The support includes a support substrate. The piezoelectric layer has a thickness in a first direction and is provided on a main surface of the support. The functional electrode is provided on a main surface of the piezoelectric layer. The piezoelectric layer includes a first piezoelectric film and a second piezoelectric film stacked on the first piezoelectric film. A polarization direction of the first piezoelectric film and a polarization direction of the second piezoelectric film are directions other than opposite directions. A displacement direction of a main wave of the first piezoelectric film and a displacement direction of a main wave of the second piezoelectric film are identical directions. A displacement direction of a spurious wave of the first piezoelectric film and a displacement direction of a spurious wave of the second piezoelectric film are opposite directions.

According to another example embodiment of the present invention, a piezoelectric device includes a support, a piezoelectric layer, and a functional electrode. The support includes a support substrate. The piezoelectric layer has a thickness in a first direction and is provided on a main surface of the support. The functional electrode is provided on a main surface of the piezoelectric layer. The piezoelectric layer includes a first piezoelectric film and a second piezoelectric film stacked on the first piezoelectric film. An a-axis direction of a lithium tantalate crystal of the first piezoelectric film and an a-axis direction of a lithium tantalate crystal of the second piezoelectric film are opposite directions.

According to another example embodiment of the present invention, a piezoelectric device includes a support, a piezoelectric layer, and a functional electrode. The support includes a support substrate. The piezoelectric layer has a thickness in a first direction and is provided on a main surface of the support. The functional electrode is provided on a main surface of the piezoelectric layer. The piezoelectric layer includes a first piezoelectric film and a second piezoelectric film stacked on the first piezoelectric film. An a-axis direction of a lithium niobate crystal of the first piezoelectric film and an a-axis direction of a lithium niobate crystal of the second piezoelectric film are opposite directions.

According to an example embodiment of the present invention, a filter includes the piezoelectric device according to any one of the example embodiments of the present invention.

According to example embodiments of the present invention, piezoelectric devices and filters each suppress spurious waves near a resonance point can be provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view illustrating an example of a piezoelectric device according to a First Example Embodiment of the present invention.

FIG. 2 is a schematic cross-sectional view taken along line II-II in FIG. 1.

FIG. 3A is a plan view illustrating the crystal orientation of a first piezoelectric film according to the First Example Embodiment of the present invention.

FIG. 3B is a plan view illustrating the crystal orientation of a second piezoelectric film according to the First Example Embodiment of the present invention.

FIG. 4A is a plan view illustrating the crystal orientation of a first piezoelectric film according to a Second Example Embodiment of the present invention.

FIG. 4B is a plan view illustrating the crystal orientation of a second piezoelectric film according to the Second Example Embodiment of the present invention.

FIG. 5A is a diagram illustrating resonance characteristics according to Comparative Example 1.

FIG. 5B is an enlarged view of a portion of the band in FIG. 5A.

FIG. 6A is a diagram illustrating resonance characteristics according to Comparative Example 2.

FIG. 6B is an enlarged view of a portion of the band in FIG. 6A.

FIG. 7A is a diagram illustrating resonance characteristics according to Comparative Example 3.

FIG. 7B is an enlarged view of a portion of the band in FIG. 7A.

FIG. 8A is a diagram illustrating resonance characteristics according to Comparative Example 4.

FIG. 8B is an enlarged view of a portion of the band in FIG. 8A.

FIG. 9A is a diagram illustrating resonance characteristics according to Comparative Example 5.

FIG. 9B is an enlarged view of a portion of the band in FIG. 9A.

FIG. 10A is a diagram illustrating resonance characteristics according to Example 1.

FIG. 10B is an enlarged view of a portion of the band in FIG. 10A.

FIG. 10C is an enlarged view of a portion of the band in FIG. 10A.

FIG. 11A is a diagram illustrating resonance characteristics according to Example 2.

FIG. 11B is an enlarged view of a portion of the band in FIG. 11A.

FIG. 11C is an enlarged view of a portion of the band in FIG. 11A.

FIG. 12A is a diagram illustrating resonance characteristics according to Example 3.

FIG. 12B is an enlarged view of a portion of the band in FIG. 12A.

FIG. 12C is an enlarged view of a portion of the band in FIG. 12A.

FIG. 13A is a diagram illustrating resonance characteristics according to Example 4.

FIG. 13B is an enlarged view of a portion of the band in FIG. 13A.

FIG. 13C is an enlarged view of a portion of the band in FIG. 13A.

FIG. 14A is a diagram illustrating resonance characteristics according to Example 5.

FIG. 14B is an enlarged view of a portion of the band in FIG. 14A.

FIG. 14C is an enlarged view of a portion of the band in FIG. 14A.

FIG. 15A is a diagram illustrating resonance characteristics according to Example 6.

FIG. 15B is an enlarged view of a portion of the band in FIG. 15A.

FIG. 16A is a diagram illustrating resonance characteristics according to Example 7.

FIG. 16B is an enlarged view of a portion of the band in FIG. 16A.

FIG. 17A is a diagram illustrating resonance characteristics according to Example 8.

FIG. 17B is an enlarged view of a portion of the band in FIG. 17A.

FIG. 18 is a diagram illustrating resonance characteristics according to Comparative Example 6.

FIG. 19A is a diagram illustrating resonance characteristics according to Comparative Example 7.

FIG. 19B is an enlarged view of a portion of the band in FIG. 19A.

FIG. 20A is a diagram illustrating resonance characteristics according to Comparative Example 8.

FIG. 20B is an enlarged view of a portion of the band in FIG. 20A.

FIG. 21A is a diagram illustrating resonance characteristics according to Comparative Example 9.

FIG. 21B is an enlarged view of a portion of the band in FIG. 21A.

FIG. 22A is a diagram illustrating resonance characteristics according to Comparative Example 10.

FIG. 22B is an enlarged view of a portion of the band in FIG. 22A.

FIG. 23A is a diagram illustrating resonance characteristics according to Example 9.

FIG. 23B is an enlarged view of a portion of the band in FIG. 23A.

FIG. 23C is an enlarged view of a portion of the band in FIG. 23A.

FIG. 24A is a diagram illustrating resonance characteristics according to Example 10.

FIG. 24B is an enlarged view of a portion of the band in FIG. 24A.

FIG. 24C is an enlarged view of a portion of the band in FIG. 24A.

FIG. 25A is a diagram illustrating resonance characteristics according to Example 11.

FIG. 25B is an enlarged view of a portion of the band in FIG. 25A.

FIG. 25C is an enlarged view of a portion of the band in FIG. 25A.

FIG. 26A is a diagram illustrating resonance characteristics according to Example 12.

FIG. 26B is an enlarged view of a portion of the band in FIG. 26A.

FIG. 26C is an enlarged view of a portion of the band in FIG. 26A.

FIG. 27A is a diagram illustrating resonance characteristics according to Example 13.

FIG. 27B is an enlarged view of a portion of the band in FIG. 27A.

FIG. 27C is an enlarged view of a portion of the band in FIG. 27A.

FIG. 28A is a diagram illustrating resonance characteristics according to Example 14.

FIG. 28B is an enlarged view of a portion of the band in FIG. 28A.

FIG. 29A is a diagram illustrating resonance characteristics according to Example 15.

FIG. 29B is an enlarged view of a portion of the band in FIG. 29A.

FIG. 30A is a diagram illustrating resonance characteristics according to Example 16.

FIG. 30B is an enlarged view of a portion of the band in FIG. 30A.

### DETAILED DESCRIPTION OF THE EXAMPLE EMBODIMENTS

Example embodiments of the present disclosure will be described in detail below with reference to the drawings. However, the present disclosure is not limited to these example embodiments. The example embodiments described in the present disclosure are illustrative examples, and descriptions of modifications in which parts of configurations of different example embodiments can be substituted for one another or combined with one another are possible and descriptions of matters common to the First Example Embodiment are omitted from the Second Example Embodiment and subsequent example embodiments, and only the points that are different are described. In particular, similar effects resulting from similar configurations will not be repeatedly described in the individual example embodiments. Furthermore, in the present disclosure, numerical values include rounded ranges. Furthermore, in the present disclosure, unless otherwise specified, positive and negative angles are distinguished from each other, with counterclockwise rotation being described as positive and clockwise rotation being described as negative. Furthermore, in the present disclosure, unless otherwise specified, one direction is described separately from the opposite direction (reverse direction) from the one direction. In other words, “one direction is the same as another direction” means that the one direction is parallel to the other direction and that the one direction and the other direction point in the same direction. Furthermore, when one direction and the other direction are opposite directions (reverse directions), the one direction and the other direction are different directions. Furthermore, in the present disclosure, directions in a Cartesian coordinate system will be described in terms of a right-handed system.

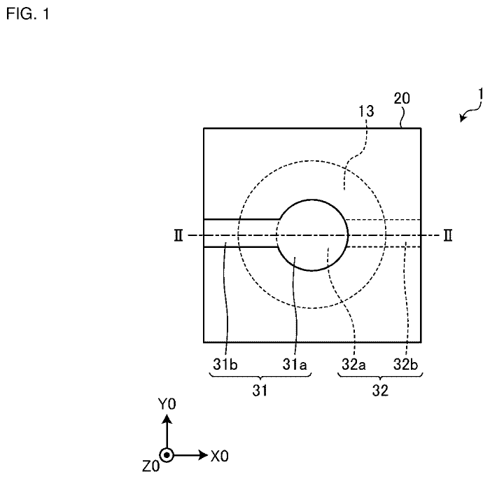

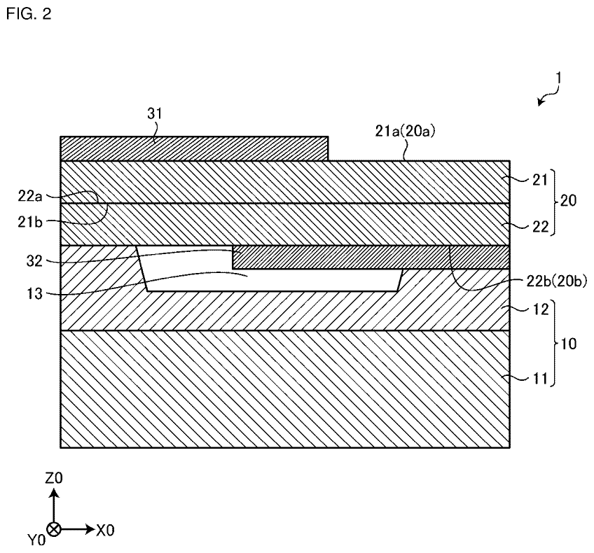

FIG. 1 is a schematic plan view illustrating an example of a piezoelectric device according to a First Example Embodiment. FIG. 2 is a schematic cross-sectional view taken along line II-II in FIG. 1. A piezoelectric device 1 according to the First Example Embodiment includes a support 10, a piezoelectric layer 20, an upper electrode 31, and a lower electrode 32. The piezoelectric device 1 is a piezoelectric element that utilizes bulk waves, i.e., a bulk acoustic wave (BAW) element. In the First Example Embodiment, the piezoelectric device 1 is a piezoelectric element configured to utilize thickness-shear vibrations of the piezoelectric layer 20. In the following description, the thickness direction of the piezoelectric layer 20 is referred to as a Z0 direction, a direction perpendicular to the Z0 direction is referred to as an X0 direction, and a direction perpendicular to the Z0 and X0 directions is referred to as a Y0 direction. In other words, the X0 direction, the Y0 direction, and the Z0 direction are directions that form a Cartesian coordinate system. In the present disclosure, the Z0 direction is an example of a “first direction”. Here, the X0 direction is a direction oriented along a side of the piezoelectric device 1 according to the First Example Embodiment, as illustrated in FIG. 1, for example. When the upper electrode 31 and the lower electrode 32 are rectangular, the X0 direction may be the direction of sides of the upper electrode 31 and the lower electrode 32.

The piezoelectric layer 20 is a flat-plate-shaped layer having a thickness in the Z0 direction. The piezoelectric layer 20 has an upper surface 20a and a lower surface 20b. The upper surface 20a and the lower surface 20b are each an example of “a main surface of the piezoelectric layer” in the present disclosure. The film thickness of the piezoelectric layer 20 is not particularly limited, but is preferably about 1 μm or less, for example. This enables good resonance characteristics to be obtained.

The piezoelectric layer 20 includes a first piezoelectric film 21 and a second piezoelectric film 22. The second piezoelectric film 22 is stacked on the first piezoelectric film 21 in the Z0 direction. That is, the first piezoelectric film 21 and the second piezoelectric film 22 form a multilayer body. The first piezoelectric film 21 has a first main surface 21a and a second main surface 21b. The second piezoelectric film 22 has a third main surface 22a and a fourth main surface 22b. In the example in FIG. 2, the first main surface 21a of the first piezoelectric film 21 corresponds to the upper surface 20a of the piezoelectric layer 20. The fourth main surface 22b of the second piezoelectric film 22 corresponds to the lower surface 20b of the piezoelectric layer 20. In addition, the second main surface 21b of the first piezoelectric film 21 and the third main surface 22a of the second piezoelectric film 22 are bonded facing each other, thereby providing a multilayer body. The first piezoelectric film 21 and the second piezoelectric film 22 define a multilayer body, which can improve the strength of the piezoelectric layer 20. Details of the first piezoelectric film 21 and the second piezoelectric film 22 will be described later.

The piezoelectric layer may be provided with a through hole that communicates with a space 13, which is described later. In this case, the through hole is provided at a position that overlaps the space 13 in plan view in the Z0 direction. The through hole may penetrate or not penetrate through the upper electrode and the lower electrode.

The upper electrode 31 is provided on the upper surface 20a of the piezoelectric layer 20. The lower electrode 32 is provided on the lower surface 20b of the piezoelectric layer 20. The upper electrode 31 and the lower electrode 32 are examples of a “functional electrode” in the present disclosure. The upper electrode 31 and the lower electrode 32 include a metal or alloy such as aluminum (Al), platinum (Pt), copper (Cu), tungsten (W), or molybdenum (Mo). The upper electrode 31 and the lower electrode 32 may each be a multilayer body including two or more layers including different materials, and may include an adhesion layer including titanium (Ti), a nickel-chromium alloy (NiCr), or the like.

As illustrated in FIG. 1, the upper electrode 31 includes a circular main electrode portion 31a and an extending portion 31b extending from the main electrode portion 31a in a direction perpendicular to the Z0 direction. The lower electrode 32 includes a circular main electrode portion 32a and an extending portion 32b extending from the main electrode portion 32a in a direction perpendicular to the Z0 direction. In a plan view in the Z0 direction, the circular main electrode portion 31a of the upper electrode 31 and the circular main electrode portion 32a of the lower electrode 32 overlap each other. In other words, the piezoelectric layer 20 is sandwiched between the circular main electrode portion 31a of the upper electrode 31 and the circular main electrode portion 32a of the lower electrode 32. As a result, bulk waves are excited in the region between the circular main electrode portion 31a of the upper electrode 31 and the circular main electrode portion 32a of the lower electrode 32. Note that the shapes of the upper electrode 31 and the lower electrode 32 are merely examples and are not limited thereto. In the following description, the region where the upper electrode 31 and the lower electrode 32 overlap in plan view in the Z0 direction may be described as an excitation region.

The support 10 is disposed opposite the lower surface 20b of the piezoelectric layer 20. In the First Example Embodiment, the support 10 includes a support substrate 11 and an intermediate layer 12. The support substrate 11 is a substrate including silicon (Si), quartz crystal, or the like. The intermediate layer 12 is disposed on the piezoelectric layer 20 side of the support substrate 11. The intermediate layer 12 includes a dielectric material such as silicon oxide.

The support 10 includes the space 13. In the example in FIG. 2, the space 13 is the space inside a recess provided on the piezoelectric layer 20 side of the intermediate layer 12. The space 13 is provided so as to overlap the excitation region when viewed in plan view in the Z0 direction. This allows bulk waves generated when the piezoelectric device 1 is driven to be reflected by the space 13. In the example in FIG. 1, the region overlapping the space 13 when viewed in plan view in the Z0 direction is circular, but this is merely an example and may be any other shape, such as rectangular.

The first piezoelectric film 21 and the second piezoelectric film 22 will be described in detail below. In the following description, when the first piezoelectric film 21 and the second piezoelectric film 22 are not particularly distinguished from each other, the first piezoelectric film 21 and the second piezoelectric film 22 may be referred to as “piezoelectric films”. In the following description, “piezoelectric material” refers to the piezoelectric material constituting the piezoelectric films, and refers to lithium tantalate (LiTaO₃) in the First and Second Example Embodiments, and to lithium niobate (LiNbO₃) in Third and Fourth Example Embodiments.

In the First Example Embodiment, the first piezoelectric film 21 and the second piezoelectric film 22 are thin films of single crystals of lithium tantalate (LiTaO₃). Lithium tantalate (LiTaO₃) has a trigonal crystal structure and has an a-axis and a c-axis as crystal axes. The a-axis and c-axis directions of the lithium tantalate (LiTaO₃) crystals of the piezoelectric films can be determined by X-ray diffraction measurement of a cross section of the piezoelectric layer 20 along the Z0 direction. In the following description, the crystal axes of the piezoelectric material are sometimes described with the a-axis being the x-axis, the c-axis being the z-axis, and the axis perpendicular to the a-axis and c-axis and forming a right-handed system with the x-axis and z-axis being the y-axis. In other words, the x-axis, y-axis, and z-axis are mutually perpendicular directions and form a Cartesian coordinate system.

In the present disclosure, when the Euler angles of the piezoelectric body of a piezoelectric film are (α, β, γ), this means that the directions of the crystal axes of the piezoelectric body (x-axis direction, y-axis direction, and z-axis direction) satisfy the condition that “the directions of the axes (x′″-axis direction, y′″-axis direction, and z′″-axis direction) obtained by rotating and moving the x-axis direction, the y-axis direction, and the z-axis direction in the order of (A), (B), and (C) given below are the same as the directions of the spatial coordinate axes (X0 direction, Y0 direction, Z0 direction), respectively”. In other words, the upper surface (the surface on the Z0 direction side) of the piezoelectric film is a surface that has the z′″-axis as its normal and contains the x′″-axis. Incidentally, the definition of right-handed system Euler angles is described in “Danseiha Soshi Handobukku” (Acoustic Wave Device Gijutsu Technology Handbook) Nippon (edited by Gakujutsu Shinkokai Danseiha Soshi Gijutsu Dai 150 Inkai (the 150th Committee on Acoustic Wave Device Technology of the Japan Society for the Promotion of Science), First Edition, First Printing, published Nov. 30, 1991, Ohmsha, p. 549). The definition of right-handed Euler angles described in the above-identified document is used in the present disclosure, and the X0 direction in the present disclosure corresponds to the propagation direction of the surface acoustic waves of the surface acoustic wave filter described in this document.

(A) Using the z-axis as the axis of rotation, the x-axis is rotated counterclockwise as viewed from the z-axis direction by a rotation angle α. As a result, x′, y′, and z′ axes are defined as the axes after rotation. Here, the z-axis is not rotated, so the z′-axis is oriented in the same direction as the z-axis.

(B) Using the x′-axis as the axis of rotation, the z′-axis is rotated counterclockwise as viewed from the x′-axis direction by a rotation angle β. As a result, x″, y″, and z″-axes are defined as the axes after rotation. Here, since the x′-axis is not rotated, the x″-axis is oriented in the same direction as the x′-axis.

(C) Using the z″-axis as the axis of rotation, the x″-axis is rotated counterclockwise as viewed from the z″-axis direction by a rotation angle γ. As a result, x′″, y′″, and z′″-axes are defined as the axes after rotation. Here, since the z″-axis is not rotated, the z′″-axis is oriented in the same direction as the z″-axis.

In the following description, the rotation angle α from the x-axis to the x′-axis may be described as the first component of the Euler angles, the rotation angle β from the z′-axis to the z″-axis may be described as the second component of the Euler angles, and the rotation angle γ from the x″-axis to the x″′-axis may be described as the third component of the Euler angles. In the present disclosure, the first component of the Euler angles will be described assuming that a counterclockwise rotation as viewed from the z-axis direction is positive and a clockwise rotation as viewed from the z-axis direction is negative. Similarly, the second component of the Euler angle will be described assuming that a counterclockwise rotation as viewed from the x′-axis direction is positive and a clockwise rotation as viewed from the x′-axis direction is negative. Similarly, the third component of the Euler angles will be described assuming that a counterclockwise rotation as viewed from the z″-axis direction is positive and a clockwise rotation as viewed from the z″-axis direction is negative.

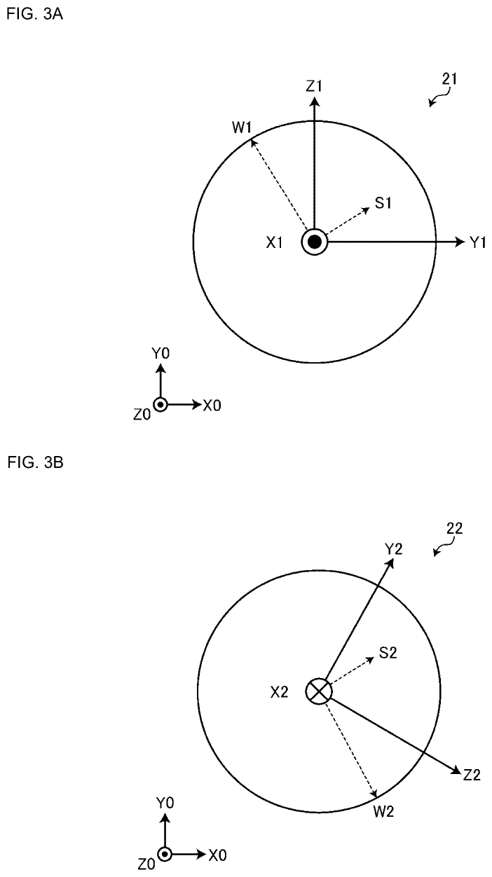

FIG. 3A is a plan view illustrating the crystal orientation of the first piezoelectric film according to the First Example Embodiment. FIG. 3B is a plan view illustrating the crystal orientation of the second piezoelectric film according to the First Example Embodiment. In the following description, the Euler angles of LiTaO₃ of the first piezoelectric film 21 are represented as (φ₁, θ₁, ψ). The Euler angles of LiTaO₃ of the second piezoelectric film 22 are represented as (φ₂, θ₂, ψ+δ). That is, δ is the difference between the third component of the Euler angles of LiTaO₃ of the second piezoelectric film 22 and the third component ψ of the Euler angles of LiTaO₃ of the first piezoelectric film 21. The x-axis direction (a-axis direction), y-axis direction, and z-axis direction (c-axis direction) of the LiTaO₃ crystal of the first piezoelectric film 21 are represented as the X1 direction, the Y1 direction, and the Z1 direction, respectively. Here, the X1 direction, the Y1 direction, and the Z1 direction are perpendicular to each other. Similarly, the x-axis direction (a-axis direction), y-axis direction, and z-axis direction (c-axis direction) of the LiTaO₃ crystal of the second piezoelectric film 22 are represented as the X2 direction, the Y2 direction, and the Z2 direction, respectively. Here, the X2 direction, the Y2 direction, and the Z2 direction are perpendicular to each other.

In the First Example Embodiment, the first piezoelectric film 21 and the second piezoelectric film 22 are thin films of X-cut lithium tantalate (LiTaO₃) single crystal. In the present disclosure, the piezoelectric material of the piezoelectric films is X-cut means that the normal to the cut surface of the piezoelectric material, i.e., the Z0-direction main surface of the piezoelectric film, is parallel to the a-axis direction of the crystal. The piezoelectric material of a piezoelectric film can be said to be X-cut if the first component of the Euler angles of the piezoelectric material of the piezoelectric film is greater than or equal to about 87° and less than or equal to about 93° or greater than or equal to about −93° and less than or equal to about −87° and the second component is greater than or equal to about 87° and less than or equal to about 93° or greater than or equal to about −93° and less than or equal to about −87°, for example. Preferably, the first component of the Euler angles of the piezoelectric material of the piezoelectric film is about 90° or about −90° and the second component is about 90° or about −90°, for example. This improves resonance characteristics.

In the First Example Embodiment, the a-axis directions (x-axis directions) of the crystals of the piezoelectric material (LiTaO₃) of the first piezoelectric film 21 and the second piezoelectric film 22 are opposite to each other. That is, the X1 direction and the X2 direction are opposite directions.

In the example in FIG. 3A, the first component of the Euler angles of the LiTaO₃ of the first piezoelectric film 21 is about 90°, the second component is about 90°, and the third component is an arbitrary value and is not particularly limited, for example. Therefore, the Euler angles of the LiTaO₃ of the first piezoelectric film 21 are expressed as (90°, 90°, ψ). Furthermore, when ψ=0, the X1 direction, Y1 direction, and Z1 direction are the same as the Z0 direction, X0 direction, and Y0 direction, respectively. ψ is the magnitude of the angle from the Y1 direction to the X0 direction when viewed in plan view from the Z0 direction, and corresponds to the magnitude of the angle from the Z1 direction to the Y0 direction. Therefore, the upper surface (first main surface 21a) of the first piezoelectric film 21 is an a-axis direction plane of the piezoelectric crystal.

In the example in FIG. 3B, the first component of the Euler angles of the LiTaO₃ of the second piezoelectric film 22 is about 90°, and the second component is about −90°, for example. Therefore, the Euler angles LiTaO₃ of the second piezoelectric film 22 are expressed as (90°, −90°, ψ+δ). Furthermore, when ψ+δ=0, the X2 direction, Y2 direction, and Z2 direction are the opposite direction of the Z0 direction and the opposite directions of the X0 direction and the Y0 direction, respectively. ψ+δ is the magnitude of the angle from the Y2 direction to the X0 direction when viewed in plan view from the Z0 direction, and corresponds to the magnitude of the angle from the Z2 direction to the Y0 direction. Therefore, the upper surface (third main surface 22a) of the second piezoelectric film 22 is a plane with an opposite direction to the a-axis direction of the piezoelectric crystal. In other words, in the example in FIGS. 3A and 3B, the first piezoelectric film 21 and the second piezoelectric film 22 are stacked so that planes of the piezoelectric crystals having opposite directions with respect to the a-axis direction face each other.

The polarization direction of the first piezoelectric film 21 and the polarization direction of the second piezoelectric film 22 are directions other than opposite directions. In the present disclosure, polarization direction refers to the direction of spontaneous polarization. The spontaneous polarization directions of the first piezoelectric film 21 and the second piezoelectric film 22 can be observed using a scanning probe microscope (SPM). Specifically, in an observation image of a cross section of the first piezoelectric film 21 and the second piezoelectric film 22 taken along the Z0 direction using a piezo response microscope (PRM), regions with different spontaneous polarization directions appear as regions showing different colors. This allows the spontaneous polarization directions of the first piezoelectric film 21 and the second piezoelectric film 22 to be measured.

In the First Example Embodiment, the polarization direction of the first piezoelectric film 21 is the Z1 direction, and the polarization direction of the second piezoelectric film 22 is the Z2 direction. As illustrated in FIGS. 3A and 3B, the Z1 direction and the Z2 direction are oriented in directions other than opposite directions in plan view in the Z0 direction. In the example illustrated in FIGS. 3A and 3B, the Z1 direction and the Z2 direction intersect each other in plan view in the Z0 direction. That is, the Z1 direction and the Z2 direction are not parallel to each other. Therefore, the polarization direction (Z1 direction) of the first piezoelectric film 21 and the polarization direction (Z2 direction) of the second piezoelectric film 22 can be said to intersect each other, and the component of the polarization direction of the first piezoelectric film 21 perpendicular to the Z0 direction and the component of the polarization direction of the second piezoelectric film 22 perpendicular to the Z0 direction can be said to intersect each other. This improves the resonance characteristics of the piezoelectric device 1.

In the First Example Embodiment, a shear direction W1 of a main wave of the first piezoelectric film 21 and a shear direction W2 of a main wave of the second piezoelectric film 22 are parallel directions. In the present disclosure, a main wave of a piezoelectric film refers to the wave of a vibration mode with which the desired resonance is obtained among the resonant wave modes of the piezoelectric device 1 in the piezoelectric film. In the present disclosure, wave modes of resonance of the piezoelectric device 1 in the piezoelectric film include a first wave with a resonant frequency approximately equal to the frequency achieved when the piezoelectric film is a single layer, and a second wave with a frequency approximately half that resonant frequency. The first wave and the second wave are generated when multiple piezoelectric films are bonded together so that their displacement directions are opposite (out of phase) or the same (in phase). When the piezoelectric material is X-cut, the wave of the mode with the larger coupling coefficient among the first and second waves is used, and therefore the wave of the mode with the larger coupling coefficient among the first and second waves is used as a main wave. Therefore, when multiple piezoelectric films are bonded together with their displacement directions in phase or out of phase, a main wave of the first piezoelectric film 21 refers to a wave of a vibration mode with which the desired resonance is obtained, among waves having approximately the same frequency as the resonant frequency obtained with a single layer of the first piezoelectric film 21 and waves having approximately half the frequency of the resonance wave, and a main wave of the second piezoelectric film 22 refers to a wave of a vibration mode with which the desired resonance is obtained, among waves having approximately the same frequency as the resonant frequency obtained with a single layer of the second piezoelectric film 22 and waves having approximately half the frequency of the resonance wave. In the present disclosure, the shear direction is an example of the “displacement direction” and refers to the direction of thickness-shear vibration. Furthermore, in the present disclosure, the displacement direction of the first piezoelectric film 21 and the displacement direction of the second piezoelectric film 22 being parallel means that, when viewed from the Z0 direction, the angle between the displacement direction of the first piezoelectric film 21 and the displacement direction of the second piezoelectric film 22 is about −20° or more and about 20° or less, or about 160° or more and about 200° or less, for example.

The shear directions of the first piezoelectric film 21 and the second piezoelectric film 22 can be calculated by measuring the crystal orientation (Euler angles) of LiTaO₃ and by simulation using the finite element method (FEM). Instead of simulation using FEM, the shear directions can also be identified by actually observing the first piezoelectric film 21 and the second piezoelectric film 22 in excitation observations.

Here, the shear directions of the first piezoelectric film 21 and the second piezoelectric film 22 are specific directions depending on the material. In the First Example Embodiment, the shear direction W1 of a main wave of the first piezoelectric film 21 is a direction perpendicular to the X1 direction, and forms an angle of about 38° with respect to the Z1 direction when viewed in plan view from the X1 direction (Z0 direction), for example. A shear direction S1 of a spurious wave of the first piezoelectric film 21 is a direction perpendicular to the X1 direction, and forms an angle of about 308° with respect to the Z1 direction when viewed in plan view from the X1 direction, for example. In the present disclosure, a spurious wave of a piezoelectric film refers to a wave of a vibration mode with which unwanted resonance is obtained among the resonant wave modes of the piezoelectric device 1 in the piezoelectric film. When the piezoelectric material is X-cut, the wave of the mode with the smaller coupling coefficient among the first wave, which has approximately the same resonant frequency as the frequency obtained when the piezoelectric film is a single layer, and the second wave, which has a frequency approximately half the resonant frequency, is not used, and therefore the wave of the mode with the smaller coupling coefficient among the first wave and the second wave is considered to be a spurious wave. Therefore, when multiple piezoelectric films are bonded together so that their displacement directions are in phase or out of phase, the spurious wave of the first piezoelectric film 21 refers to the wave that is not a main wave among the wave that has approximately the same frequency resonant frequency obtained when the first piezoelectric film 21 is a single layer and the wave that is approximately half the frequency of the resonant wave, and the spurious wave of the second piezoelectric film 22 refers to the wave that is not a main wave among the wave that has approximately the same frequency as the resonant frequency obtained when the second piezoelectric film 22 is a single layer and the wave that is approximately half the frequency of the resonant wave. Similarly to the first piezoelectric film 21, the shear direction W2 of a main wave of the second piezoelectric film 22 is perpendicular to the X2 direction and forms an angle of about 38° with respect to the Z2 direction when viewed in plan view from the X2 direction, whereas the shear direction S2 of a spurious wave of the second piezoelectric film 22 is perpendicular to the X2 direction and forms an angle of about 308° with respect to the Z2 direction when viewed in plan view from the X2 direction, for example. In other words, the shear direction W2 of a main wave of the second piezoelectric film 22 is a direction that forms an angle of about 322° with respect to the Z2 direction when viewed in plan view from the opposite direction from the X2 direction (Z0 direction), and the shear direction S2 of the spurious wave is a direction that forms an angle of about 52° with respect to the Z2 direction when viewed in plan view from the opposite direction from the X2 direction (Z0 direction), for example.

In the First Example Embodiment, the shear direction W1 of a main wave of the first piezoelectric film 21 and the shear direction W2 of a main wave of the second piezoelectric film 22 are opposite directions. In the present disclosure, “the two displacement directions are opposite directions” refers to the two displacement directions being parallel but oriented opposite to each other when the same potential is applied. On the other hand, in the First Example Embodiment, the shear direction S1 of the spurious wave generated in the first piezoelectric film 21 and the shear direction S2 of the spurious wave generated in the second piezoelectric film 22 are the same direction. In the present disclosure, “the two displacement directions are the same direction” means that the two displacement directions are parallel, but when the same potential is applied, the two displacement directions are oriented in the same direction. As a result, a main wave is excited at approximately the same frequency as when the piezoelectric layer is a single layer including the first piezoelectric film. On the other hand, spurious waves are excited at approximately the same frequency as when the piezoelectric layer is a single layer including the first piezoelectric film and the thickness of the first piezoelectric film is doubled. Therefore, compared to when the piezoelectric layer is a single layer including the first piezoelectric film, the frequency of the spurious waves alone can be reduced to approximately half, which means that the spurious waves can be kept away from the resonance point and spurious waves near the resonance point can be suppressed.

Although an example of a piezoelectric device according to the First Example Embodiment has been described above, a piezoelectric device according to the First Example Embodiment is not limited to the one described above.

For example, the X1 direction may be opposite to the Z0 direction, and the X2 direction may be the same as the Z0 direction. In this case, the positions of the first piezoelectric film 21 and the second piezoelectric film 22 are not limited to the example in FIG. 2, and the third main surface 22a of the second piezoelectric film 22 is the upper surface 20a, and the second main surface 21b of the first piezoelectric film 21 is the lower surface 20b of the piezoelectric layer 20. That is, the first piezoelectric film 21 and the second piezoelectric film 22 are stacked so that the first main surface 21a (the surface on the X1 direction side) of the first piezoelectric film 21 and the fourth main surface 22b (the surface on the X2 direction side) of the second piezoelectric film 22 face each other. In other words, the first piezoelectric film 21 and the second piezoelectric film 22 are stacked so that the a-axis-direction surfaces of the piezoelectric crystals face each other.

For example, the piezoelectric layer is not limited to including the first piezoelectric film 21 and the second piezoelectric film 22, and may include further piezoelectric films stacked therein. That is, the piezoelectric layer may include three or more piezoelectric films.

For example, a layer different from the first piezoelectric film 21 and the second piezoelectric film 22, such as a layer including silicon oxide (SiO₂) or an adhesive layer, may be provided between the first piezoelectric film 21 and the second piezoelectric film 22.

For example, the upper electrode 31 and the lower electrode 32 may have a rectangular shape with a longitudinal direction when viewed in plan view in the Z0 direction. In this case, the longitudinal direction of the upper electrode 31 and the lower electrode 32 may be parallel to or perpendicular to the shear directions W1 and W2 of main waves.

For example, a frame-shaped electrode may be further provided on the upper surface 20a or the lower surface 20b of the piezoelectric layer 20 so as to surround the upper electrode 31 and the lower electrode 32 in plan view in the Z0 direction.

For example, an acoustic multilayer film may be provided in the support 10 instead of the space 13. The acoustic multilayer film has a multilayer structure including a low acoustic impedance layer having a relatively low acoustic impedance and a high acoustic impedance layer having a relatively high acoustic impedance. The low acoustic impedance layer is, for example, a dielectric film such as SiO₂, SiOC, or a polymer, or a metal layer such as Al. The high acoustic impedance layer is, for example, a metal layer such as W, Pt, or Mo, or a dielectric layer such as tantalum oxide, tungsten oxide, or aluminum nitride. When an acoustic multilayer film is used, bulk waves of thickness-shear vibration can be confined within the piezoelectric layer 20 without use of the space 13.

For example, the materials of the first and second piezoelectric films are not limited to LiTaO₃ and LiNbO₃, and may be materials that excite modes other than shear modes. In this case, the relationship between the displacement direction of the first piezoelectric film and the displacement direction of the second piezoelectric film can be the same as or similar to the relationship between the shear direction of the first piezoelectric film and the shear direction of the second piezoelectric film described above. That is, the displacement direction of a main wave of the first piezoelectric film and the displacement direction of a main wave of the second piezoelectric film are parallel directions. Furthermore, as described above, the displacement direction of a main wave of the first piezoelectric film and the displacement direction of a main wave of the second piezoelectric film may be opposite directions, and the displacement direction of a spurious wave of the first piezoelectric film and the displacement direction of a spurious wave of the second piezoelectric film may be the same direction. Furthermore, similarly to a Second Example Embodiment described later, the displacement direction of a main wave of the first piezoelectric film and the displacement direction of a main wave of the second piezoelectric film may be the same direction, and the displacement direction of the spurious wave of the first piezoelectric film and the displacement direction of the spurious wave of the second piezoelectric film may be opposite directions.

As described above, the piezoelectric device 1 according to the First Example Embodiment includes the support 10 including the support substrate 11, the piezoelectric layer 20 having a thickness in the first direction and provided on a main surface of the support 10, and functional electrodes (upper electrode 31 and lower electrode 32) provided on the main surfaces (upper surface 20a and lower surface 20b) of the piezoelectric layer 20. The piezoelectric layer 20 includes the first piezoelectric film 21 and the second piezoelectric film 22 stacked on the first piezoelectric film 21. The polarization directions of the first piezoelectric film 21 and the second piezoelectric film 22 are directions that intersect each other. The displacement direction of a main wave of the first piezoelectric film 21 and the displacement direction of a main wave of the second piezoelectric film 22 are parallel to each other. This allows the frequency of spurious waves or main waves to be adjusted to move the spurious waves away from the resonance point and suppressing spurious waves near the resonance point.

In an example embodiment, the component of the polarization direction of the first piezoelectric film 21 that is perpendicular to the first direction and the component of the polarization direction of the second piezoelectric film 22 that is perpendicular to the first direction are oriented in directions that intersect each other. This allows good resonance characteristics to be obtained.

In an example embodiment, the first piezoelectric film 21 and the second piezoelectric film 22 include lithium tantalate. This allows good resonance characteristics to be obtained.

In a more preferable example embodiment, the first piezoelectric film 21 and the second piezoelectric film 22 include X-cut lithium tantalate single crystal. This allows good resonance characteristics to be obtained.

In a more preferable example embodiment, the a-axis direction (X1 direction) of the lithium tantalate crystal of the first piezoelectric film 21 and the a-axis direction (X2 direction) of the lithium tantalate crystal of the second piezoelectric film 22 are opposite directions. This makes it possible to keep spurious waves away from the resonance point and suppress spurious waves near the resonance point.

In a more preferable example embodiment, when the Euler angles of the lithium tantalate of the first piezoelectric film 21 are (φ₁, θ₁, ψ), the Euler angles of the lithium tantalate of the second piezoelectric film 22 are expressed as (φ₂, θ₂, ψ+δ), where φ₁ is about 87° or more and about 93° or less, θ₁ is about 87° or more and about 93° or less, φ₂ is about 87° or more and about 93° or less, θ₂ is about −930 or more and about −87° or less, and δ is about 280° or more and about 318° or less, for example. This reduces the frequency of spurious waves to approximately half that when the piezoelectric layer 20 is a single layer including the first piezoelectric film 21 to keep spurious waves away from the resonance point and suppressing s near the resonance point.

In a more preferable example embodiment, δ is about 298° or more and about 304° or less, for example. This makes it possible to further suppress spurious waves on the low frequency side of the resonant frequency of the piezoelectric device 1.

In a more preferable example embodiment, δ is about 289° or more and about 295° or less, for example. This makes it possible to further suppress spurious waves on the high frequency side of the anti-resonant frequency of the piezoelectric device 1.

The piezoelectric device 1 according to the First Example Embodiment includes the support 10 including the support substrate 11, the piezoelectric layer 20 having a thickness in the first direction and provided on a main surface of the support 10, and functional electrodes (upper electrode 31 and lower electrode 32) provided on the main surfaces (upper surface 20a and lower surface 20b) of the piezoelectric layer 20. The piezoelectric layer 20 includes the first piezoelectric film 21 and the second piezoelectric film 22 stacked on the first piezoelectric film 21. The polarization direction of the first piezoelectric film 21 and the polarization direction of the second piezoelectric film 22 are oriented in directions other than opposite directions. The displacement direction of a main wave of the first piezoelectric film 21 and the displacement direction of a main wave of the second piezoelectric film 22 are opposite directions, and the displacement direction of a spurious wave of the first piezoelectric film 21 and the displacement direction of a spurious wave of the second piezoelectric film 22 are the same direction.

In an example embodiment, the component of the polarization direction of the first piezoelectric film 21 that is perpendicular to the first direction and the component of the polarization direction of the second piezoelectric film 22 that is perpendicular to the first direction are directions other than opposite directions. This allows good resonance characteristics to be obtained.

The piezoelectric device 1 according to the First Example Embodiment includes the support 10 including the support substrate 11, the piezoelectric layer 20 having a thickness in the first direction and provided on a main surface of the support 10, and functional electrodes (upper electrode 31 and lower electrode 32) provided on the main surfaces (upper surface 20a and lower surface 20b) of the piezoelectric layer 20. The piezoelectric layer 20 includes the first piezoelectric film 21 and the second piezoelectric film 22 stacked on the first piezoelectric film 21. The a-axis direction of the lithium tantalate crystal of the first piezoelectric film 21 and the a-axis direction of the lithium tantalate crystal of the second piezoelectric film are oriented in opposite directions. This makes it possible to keep spurious waves away from the resonance point and suppress spurious waves near the resonance point.

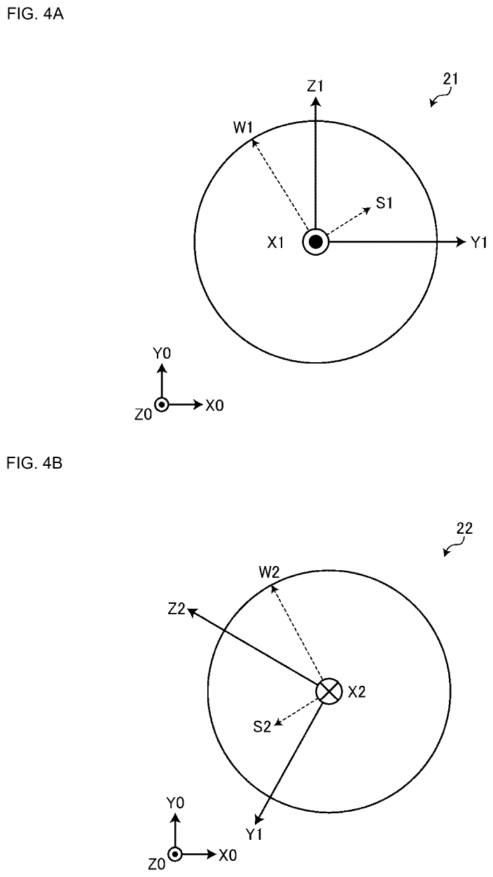

FIG. 4A is a plan view illustrating the crystal orientation of a first piezoelectric film according to a Second Example Embodiment. FIG. 4B is a plan view illustrating the crystal orientation of a second piezoelectric film according to the Second Example Embodiment. The Second Example Embodiment differs from the First Example Embodiment in that the displacement direction of a main wave of the first piezoelectric film 21, i.e., the shear direction W1 of a main wave excited in the first piezoelectric film 21, and the displacement direction of a main wave of the second piezoelectric film 22, i.e., the shear direction W2 of a main wave excited in the second piezoelectric film 22, are the same direction. On the other hand, in the Second Example Embodiment, the shear direction S1 of a spurious wave generated in the first piezoelectric film 21 and the shear direction S2 of a spurious wave generated in the second piezoelectric film 22 are opposite directions. As a result, the spurious waves are excited at approximately the same frequency as when the piezoelectric layer 20 is a single layer including the first piezoelectric film 21. On the other hand, main waves are excited at approximately the same frequency as when the piezoelectric layer 20 is a single layer including the first piezoelectric film 21 and the thickness of the first piezoelectric film 21 is doubled. Therefore, compared to when the piezoelectric layer 20 is a single layer including the first piezoelectric film 21, the frequency of only a main wave can be reduced to approximately half, so the resonance point can be moved away from spurious waves and spurious waves near the resonance point can be suppressed.

In the piezoelectric device according to the Second Example Embodiment, when the Euler angles of the lithium tantalate of the first piezoelectric film 21 are (φ₁, θ₁, ψ), the Euler angles of the lithium tantalate of the second piezoelectric film 22 are expressed as (φ₂, θ₂, ψ+δ). φ₁ is about 87° or more and about 93° or less, θ₁ is about 87° or more and about 93° or less, φ₂ is about 87° or more and about 93° or less, θ₂ is about −93° or more and about −87° or less, and δ is about 1030 or more and about 129° or less, for example. This reduces the frequency of main waves to approximately half compared to when a single layer of the first piezoelectric film 21 is used as the piezoelectric layer 20. This keeps the resonance point away from spurious waves and suppresses spurious waves near the resonance point.

In an example embodiment, δ is about 113° or more and about 119° or less, for example. This makes it possible to suppress spurious waves.

The piezoelectric device according to the Second Example Embodiment includes the support 10 including the support substrate 11, the piezoelectric layer 20 having a thickness in the first direction and provided on a main surface of the support 10, and functional electrodes (upper electrode 31 and lower electrode 32) provided on the main surfaces (upper surface 20a and lower surface 20b) of the piezoelectric layer 20. The piezoelectric layer 20 includes the first piezoelectric film 21 and the second piezoelectric film 22 stacked on the first piezoelectric film 21. The polarization direction of the first piezoelectric film 21 and the polarization direction of the second piezoelectric film 22 are oriented in directions other than opposite directions. The displacement direction of a main wave of the first piezoelectric film 21 and the displacement direction of a main wave of the second piezoelectric film 22 are the same direction, and the displacement direction of a spurious wave of the first piezoelectric film 21 and the displacement direction of a spurious wave of the second piezoelectric film 22 are opposite directions.

In an example embodiment, the component of the polarization direction of the first piezoelectric film 21 that is perpendicular to the first direction and the component of the polarization direction of the second piezoelectric film 22 that is perpendicular to the first direction are oriented in directions that intersect each other. This allows good resonance characteristics to be obtained.

In an example embodiment, the component of the polarization direction of the first piezoelectric film 21 that is perpendicular to the first direction and the component of the polarization direction of the second piezoelectric film 22 that is perpendicular to the first direction are directions other than opposite directions. This allows good resonance characteristics to be obtained.

A Third Example Embodiment differs from the First Example Embodiment in that the first piezoelectric film 21 and the second piezoelectric film 22 are thin films of single crystals of X-cut lithium niobate (LiNbO₃). The Third Example Embodiment will be described below, but descriptions of configurations that are the same as or similar to those in the First Example Embodiment will be omitted.

Lithium niobate (LiNbO₃) has a trigonal crystal structure and has an a-axis and a c-axis as crystal axes. Here, the directions of the a-axis and c-axis of the lithium niobate (LiNbO₃) crystal of the piezoelectric films can be determined by X-ray diffraction measurement of a cross section of the piezoelectric layer 20 along the Z0 direction. In the following description, the x-axis, y-axis, and z-axis will be described using the same definitions as in the First Example Embodiment for the crystal axes of the piezoelectric material.

In the following description, as in the First Example Embodiment, the Euler angles of the LiNbO₃ of the first piezoelectric film 21 are represented as (φ₁, θ₁, ψ). The Euler angles of the LiNbO₃ of the second piezoelectric film 22 are represented as (φ₂, θ₂, ψ+δ). That is, δ is the difference between the third component ψ of the Euler angles of the LiNbO₃ of the first piezoelectric film 21 and the third component of the Euler angles of the LiNbO₃ of the second piezoelectric film 22. The x-axis direction (a-axis direction), y-axis direction, and z-axis direction of the LiNbO₃ crystal of the first piezoelectric film 21 are represented as the X1 direction, the Y1 direction, and the Z1 direction, respectively. Here, the X1 direction, the Y1 direction, and the Z1 direction are perpendicular to each other. Similarly, the x-axis direction (a-axis direction), y-axis direction, and z-axis direction of the LiNbO₃ crystal of the second piezoelectric film 22 are represented as the X2 direction, the Y2 direction, and the Z2 direction, respectively. Here, the X2 direction, the Y2 direction, and the Z2 direction are perpendicular to each other.

In the Third Example Embodiment as well, the a-axis directions (x-axis directions) of the crystals of the piezoelectric (LiNbO₃) of the first piezoelectric film 21 and the second piezoelectric film 22 are oriented in opposite directions from each other. That is, the X1 direction and the X2 direction are opposite directions. In the Third Example Embodiment, as in the First Example Embodiment, for example, the Euler angles of the LiNbO₃ of the first piezoelectric film 21 are expressed as (90°, 90°, ψ), and the Euler angles of the LiNbO₃ of the second piezoelectric film 22 are expressed as (90°, −90°, ψ+δ).

In the Third Example Embodiment as well, the polarization direction of the first piezoelectric film 21 is the Z1 direction, the polarization direction of the second piezoelectric film 22 is the Z2 direction, and the Z1 direction and the Z2 direction are directions other than opposite directions when viewed in plan view in the Z0 direction. For example, the Z1 direction and the Z2 direction are directions that intersect each other when viewed in plan view in the Z0 direction. That is, the Z1 direction and the Z2 direction are not parallel to each other. Therefore, the polarization direction (Z1 direction) of the first piezoelectric film 21 and the polarization direction (Z2 direction) of the second piezoelectric film 22 can be said to intersect each other, and the component of the polarization direction of the first piezoelectric film 21 perpendicular to the Z0 direction and the component of the polarization direction of the second piezoelectric film 22 perpendicular to the Z0 direction can be said to intersect each other.

In the Third Example Embodiment, the shear direction W1 of a main wave of the first piezoelectric film 21 is perpendicular to the X1 direction and forms an angle of about 25° with respect to the Z1 direction when viewed from the X1 direction (Z0 direction) in plan view, for example. The shear direction S1 of a spurious wave of the first piezoelectric film 21 is perpendicular to the X1 direction and forms an angle of about 295° with respect to the Z1 direction when viewed from the X1 direction (Z0 direction) in plan view, for example. Similarly to the first piezoelectric film 21, the shear direction W2 of a main wave of the second piezoelectric film 22 is perpendicular to the X2 direction and forms an angle of about 25° with respect to the Z2 direction when viewed from the X2 direction in plan view, for example. The shear direction S2 of a spurious wave of the second piezoelectric film 22 is perpendicular to the X2 direction and forms an angle of about 295° with respect to the Z2 direction when viewed from the X2 direction in plan view, for example. In other words, the shear direction W2 of a main wave of the second piezoelectric film 22 is a direction that forms an angle of about 335° with respect to the Z2 direction when viewed in plan view from the opposite direction from the X2 direction (Z0 direction), and the shear direction S2 of the spurious wave is a direction that forms an angle of about 65° with respect to the Z2 direction when viewed in plan view from the opposite direction from the X2 direction (Z0 direction), for example.

In the Third Example Embodiment, similarly to the First Example Embodiment, the shear direction W1 of a main wave of the first piezoelectric film 21 and the shear direction W2 of a main wave of the second piezoelectric film 22 are opposite directions, and the shear direction S1 of the spurious wave generated in the first piezoelectric film 21 and the shear direction S2 of the spurious wave generated in the second piezoelectric film 22 are the same direction. This makes it possible to reduce the frequency of the spurious wave to about half compared to when the piezoelectric layer is a single layer including the first piezoelectric film, so that the spurious wave can be kept away from the resonance point and a spurious wave near the resonance point can be suppressed.

Similarly to the First Example Embodiment, the shear directions of the first piezoelectric film 21 and the second piezoelectric film 22 can be calculated by measuring the crystal orientation (Euler angles) of LiNbO₃ and by simulation using FEM. Instead of simulation using FEM, the shear directions can also be identified by actually observing the first piezoelectric film and the second piezoelectric film in excitation observations.

As described above, in the piezoelectric device according to the Third Example Embodiment, the first piezoelectric film 21 and the second piezoelectric film 22 include lithium niobate. This allows the frequency of spurious waves or main waves to be adjusted to move the spurious waves away from the resonance point and suppressing spurious waves near the resonance point. This allows good resonance characteristics to be obtained.

In an example embodiment, the first piezoelectric film 21 and the second piezoelectric film 22 include X-cut lithium niobate single crystal. This allows good resonance characteristics to be obtained.

In a more preferable example embodiment, the a-axis direction (X1 direction) of the lithium niobate crystal of the first piezoelectric film 21 and the a-axis direction (X2 direction) of the lithium niobate crystal of the second piezoelectric film 22 are opposite directions. This makes it possible to keep spurious waves away from the resonance point and suppress spurious waves near the resonance point.

In a more preferable example embodiment, when the Euler angles of the lithium niobate of the first piezoelectric film 21 are (φ₁, θ₁, ψ), the Euler angles of the lithium niobate of the second piezoelectric film 22 are expressed as (φ₂, θ₂, ψ+δ), where φ₁ is about 87° or more and about 93° or less, θ₁ is about 87° or more and about 93° or less, φ₂ is about 87° or more and about 93° or less, θ₂ is about −93° or more and about −87° or less, and δ is about 280° or more and about 318° or less, for example. This reduces the frequency of spurious waves to approximately half that when the piezoelectric layer 20 is a single layer including the first piezoelectric film 21 to keep spurious waves away from the resonance point and suppressing spurious waves near the resonance point.

In a more preferable example embodiment, δ is about 296° or more and about 302° or less, for example. This makes it possible to further suppress spurious waves on the low frequency side relative to the resonant frequency of the piezoelectric device.

In a more preferable example embodiment, δ is about 286° or more and about 292° or less, for example. This makes it possible to further suppress spurious waves on the high frequency side relative to the anti-resonant frequency of the piezoelectric device.

The piezoelectric device according to the Third Example Embodiment includes the support 10 including the support substrate 11, the piezoelectric layer 20 having a thickness in a first direction and provided on a main surface of the support 10, and functional electrodes (upper electrode 31 and lower electrode 32) provided on the main surfaces (upper surface 20a and lower surface 20b) of the piezoelectric layer 20. The piezoelectric layer 20 includes the first piezoelectric film 21 and the second piezoelectric film 22 stacked on the first piezoelectric film 21. The a-axis direction of the lithium niobate crystal of the first piezoelectric film 21 is oriented in the opposite direction to the a-axis direction of the lithium niobate crystal of the second piezoelectric film. This makes it possible to keep spurious waves away from the resonance point and suppress spurious waves near the resonance point.

The Fourth Example Embodiment differs from the Third Example Embodiment in that the displacement direction of a main wave of the first piezoelectric film 21 is the same as the displacement direction of a main wave of the second piezoelectric film 22. On the other hand, in the Fourth Example Embodiment, the shear direction S1 of a spurious wave generated in the first piezoelectric film 21 is oriented in the opposite direction from the shear direction S2 of a spurious wave generated in the second piezoelectric film 22. This makes it possible to reduce the frequency of a main wave to approximately half that in the case where the piezoelectric layer is a single layer including the first piezoelectric film, thereby making it possible to move the resonance point away from the spurious wave and suppress a spurious wave near the resonance point.

In the piezoelectric device according to the Fourth Example Embodiment, when the Euler angles of the lithium niobate of the first piezoelectric film 21 are (φ₁, θ₁, ψ), the Euler angles of the lithium niobate of the second piezoelectric film 22 are expressed as (φ₂, θ₂, ψ+δ), where φ₁ is about 87° or more and about 93° or less, θ₁ is about 87° or more and about 93° or less, φ₂ is about 87° or more and about 93° or less, θ₂ is about −93° or more and about −87° or less, and δ is about 101° or more and about 127° or less, for example. As a result, as in the Second Example Embodiment, the frequency of a main wave can be reduced to approximately half compared to when the piezoelectric layer 20 is a single layer including the first piezoelectric film 21, and therefore the resonance point can be moved away from spurious waves, and spurious waves near the resonance point can be suppressed.

In an example embodiment, δ is about 111° or more and about 117° or less, for example. This makes it possible to suppress spurious waves.

A filter according to a Fifth Example Embodiment is a filter including at least one piezoelectric device among the piezoelectric devices of the first to Fourth Example Embodiments described above. That is, at least one of the resonators of the filter according to the Fifth Example Embodiment is any one of the piezoelectric devices according to the first to Fourth Example Embodiments. This makes it possible to suppress spurious waves near the resonance point, thereby suppressing spurious waves near the passband of the filter.

Examples will be described below. Table 1 is a table for explaining examples and comparative examples. Here, in Table 1, “piezoelectric material” refers to the piezoelectric materials that constitute the first piezoelectric film and the second piezoelectric film.

TABLE 1

| | | | | X2 | EULER |
|---|---|---|---|---|---|
| | | | | DIRECTION | ANGLES |
| | | | | RELATIVE | OF FIRST |
| | PIEZOELECTRIC | NUMBER OF | | TO X1 | PIEZOELECTRIC |
| | MATERIAL | LAYERS | δ (°) | DIRECTION | FILM |
| COMPARATIVE | — | ONE | — | — | (90°, 90°, Ψ) |
| EXAMPLE 1 | | | | | |
| COMPARATIVE | LiTaO₃ | TWO | 180 | SAME DIRECTION | (90°, 90°, Ψ) |
| EXAMPLE 2 | | | | | |
| COMPARATIVE | LiTaO₃ | TWO | 195 | SAME DIRECTION | (90°, 90°, Ψ) |
| EXAMPLE 3 | | | | | |
| COMPARATIVE | LiTaO₃ | TWO | 180.2 | SAME DIRECTION | (90°, 90°, Ψ) |
| EXAMPLE 4 | | | | | |
| COMPARATIVE | LiTaO₃ | TWO | 180.4 | SAME DIRECTION | (90°, 90°, Ψ) |
| EXAMPLE 5 | | | | | |
| EXAMPLE 1 | LiTaO₃ | TWO | 318 | OPPOSITE DIRECTION | (90°, 90°, Ψ) |
| EXAMPLE 2 | LiTaO₃ | TWO | 299 | OPPOSITE DIRECTION | (90°, 90°, Ψ) |
| EXAMPLE 3 | LiTaO₃ | TWO | 280 | OPPOSITE DIRECTION | (90°, 90°, Ψ) |
| EXAMPLE 4 | LiTaO₃ | TWO | 301 | OPPOSITE DIRECTION | (90°, 90°, Ψ) |
| EXAMPLE 5 | LiTaO₃ | TWO | 292 | OPPOSITE DIRECTION | (90°, 90°, Ψ) |
| EXAMPLE 6 | LiTaO₃ | TWO | 129 | OPPOSITE DIRECTION | (90°, 90°, Ψ) |
| EXAMPLE 7 | LiTaO₃ | TWO | 116 | OPPOSITE DIRECTION | (90°, 90°, Ψ) |
| EXAMPLE 8 | LiTaO₃ | TWO | 103 | OPPOSITE DIRECTION | (90°, 90°, Ψ) |
| COMPARATIVE | LiNbO₃ | ONE | — | — | (90°, 90°, Ψ) |
| EXAMPLE 6 | | | | | |
| COMPARATIVE | LiNbO₃ | TWO | 180 | SAME DIRECTION | (90°, 90°, Ψ) |
| EXAMPLE 7 | | | | | |
| COMPARATIVE | LiNbO₃ | TWO | 195 | SAME DIRECTION | (90°, 90°, Ψ) |
| EXAMPLE 8 | | | | | |
| COMPARATIVE | LiNbO₃ | TWO | 180.2 | SAME DIRECTION | (90°, 90°, Ψ) |
| EXAMPLE 9 | | | | | |
| COMPARATIVE | LiNbO₃ | TWO | 180.4 | SAME DIRECTION | (90°, 90°, Ψ) |
| EXAMPLE 10 | | | | | |
| EXAMPLE 9 | LiNbO₃ | TWO | 318 | OPPOSITE DIRECTION | (90°, 90°, Ψ) |
| EXAMPLE 10 | LiNbO₃ | TWO | 301 | OPPOSITE DIRECTION | (90°, 90°, Ψ) |
| EXAMPLE 11 | LiNbO₃ | TWO | 280 | OPPOSITE DIRECTION | (90°, 90°, Ψ) |
| EXAMPLE 12 | LiNbO₃ | TWO | 299 | OPPOSITE DIRECTION | (90°, 90°, Ψ) |
| EXAMPLE 13 | LiNbO₃ | TWO | 289 | OPPOSITE DIRECTION | (90°, 90°, Ψ) |
| EXAMPLE 14 | LiNbO₃ | TWO | 127 | OPPOSITE DIRECTION | (90°, 90°, Ψ) |
| EXAMPLE 15 | LiNbO₃ | TWO | 114 | OPPOSITE DIRECTION | (90°, 90°, Ψ) |
| EXAMPLE 16 | LiNbO₃ | TWO | 101 | OPPOSITE DIRECTION | (90°, 90°, Ψ) |

| | EULER | | | | | |
|---|---|---|---|---|---|---|
| | ANGLES | | | | | |
| | OF SECOND | | ANTI- | FREQUENCIES | | |
| | PIEZO- | RESONANT | RESONANT | OF SPURIOUS | | |
| | ELECTRIC | FREQUENCY | FREQUENCY | WAVES | | |
| | FILM | (GHz) | (GHz) | (GHz) | | |
| COMPARATIVE | — | 6.3 | 7.0 | — | 5.7 | — |
| EXAMPLE 1 | | | | | | |
| COMPARATIVE | (90°, 90°, Ψ + δ) | 7.0 | 7.6 | — | 6.2 | — |
| EXAMPLE 2 | | | | | | |
| COMPARATIVE | (90°, 90°, Ψ + δ) | 7.0 | 7.6 | 3.0 | 6.2 | 9.1 |
| EXAMPLE 3 | | | | | | |
| COMPARATIVE | (90°, 90°, Ψ + δ) | 7.0 | 7.6 | — | 6.2 | — |
| EXAMPLE 4 | | | | | | |
| COMPARATIVE | (90°, 90°, Ψ + δ) | 7.0 | 7.6 | — | 6.2 | — |
| EXAMPLE 5 | | | | | | |
| EXAMPLE 1 | (90°, −90°, Ψ + δ) | 6.9 | 7.5 | 3.1 | — | 9.2 |
| EXAMPLE 2 | (90°, −90°, Ψ + δ) | 7.0 | 7.6 | 3.1 | — | 9.1 |
| EXAMPLE 3 | (90°, −90°, Ψ + δ) | 7.0 | 7.6 | 3.1 | — | 9.1 |
| EXAMPLE 4 | (90°, −90°, Ψ + δ) | 7.0 | 7.6 | — | — | 9.1 |
| EXAMPLE 5 | (90°, −90°, Ψ + δ) | 7.0 | 7.6 | 3.1 | — | — |
| EXAMPLE 6 | (90°, −90°, Ψ + δ) | 3.5 | 3.9 | 6.2 | — | — |
| EXAMPLE 7 | (90°, −90°, Ψ + δ) | 3.5 | 3.9 | — | — | — |
| EXAMPLE 8 | (90°, −90°, Ψ + δ) | 3.5 | 3.9 | 6.2 | — | — |
| COMPARATIVE | — | 5.8 | 7.4 | — | 6.4 | — |
| EXAMPLE 6 | | | | | | |
| COMPARATIVE | (90°, 90°, Ψ + δ) | 6.3 | 8.2 | — | 7.1 | — |
| EXAMPLE 7 | | | | | | |
| COMPARATIVE | (90°, 90°, Ψ + δ) | 6.3 | 8.2 | 3.6 | 7.1 | 10.3 |
| EXAMPLE 8 | | | | | | |
| COMPARATIVE | (90°, 90°, Ψ + δ) | 6.3 | 8.2 | — | 7.1 | — |
| EXAMPLE 9 | | | | | | |
| COMPARATIVE | (90°, 90°, Ψ + δ) | 6.3 | 8.2 | — | 7.1 | — |
| EXAMPLE 10 | | | | | | |
| EXAMPLE 9 | (90°, −90°, Ψ + δ) | 6.4 | 8.2 | 3.6 | — | 10.4 |
| EXAMPLE 10 | (90°, −90°, Ψ + δ) | 6.4 | 8.2 | 3.6 | — | 10.4 |
| EXAMPLE 11 | (90°, −90°, Ψ + δ) | 6.4 | 8.2 | 3.6 | — | 10.4 |
| EXAMPLE 12 | (90°, −90°, Ψ + δ) | 6.4 | 8.2 | — | — | 10.4 |
| EXAMPLE 13 | (90°, −90°, Ψ + δ) | 6.4 | 8.2 | 3.6 | — | — |
| EXAMPLE 14 | (90°, −90°, Ψ + δ) | 3.2 | 4.2 | 7.1 | — | — |
| EXAMPLE 15 | (90°, −90°, Ψ + δ) | 3.2 | 4.2 | 7.1 | — | — |
| EXAMPLE 16 | (90°, −90°, Ψ + δ) | 3.2 | 4.2 | 7.1 | — | — |

In Comparative Example 1, the piezoelectric layer was a single layer including the first piezoelectric film. Here, the first piezoelectric film was an X-cut LiTaO₃ single crystal with a thickness of 0.25 μm, for example. The Euler angles of the LiTaO₃ of the first piezoelectric film were (90°, 90°, ψ). Simulations were performed for the piezoelectric device of Comparative Example 1 in order to determine the impedance characteristics.

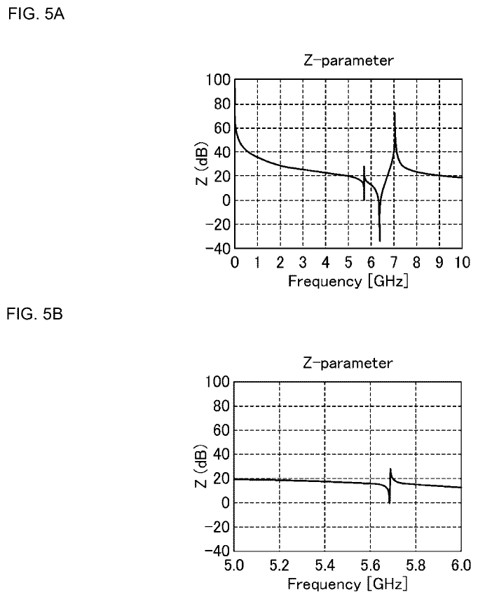

FIG. 5A is a diagram illustrating the resonance characteristics according to Comparative Example 1. FIG. 5B is a diagram illustrating an enlarged view of a portion of the band in FIG. 5A. As illustrated in Table 1, FIG. 5A, and FIG. 5B, the piezoelectric device according to Comparative Example 1 had a resonant frequency of 6.3 GHZ, an anti-resonant frequency of 7.0 GHz, and a spurious wave occurred at 5.7 GHZ.

In Comparative Example 2, the piezoelectric layer had a two-layer structure including the first piezoelectric film and the second piezoelectric film. The first piezoelectric film and the second piezoelectric film were X-cut LiTaO₃ single crystals with a thickness of 0.25 μm. The Euler angles of the LiTaO₃ of the first piezoelectric film were (90°, 90°, ψ). The Euler angles of the LiTaO₃ of the second piezoelectric film were (90°, 90°, ψ+δ). That is, in Comparative Example 2, the X1 direction and the X2 direction were the same. Therefore, ψ+δ in Comparative Example 2 is the angle between the Y2 direction and the X0 direction when viewed in plan view from the Z0 direction, and corresponds to the angle between the Z2 direction and the Y0 direction. As illustrated in Table 1, δ was set to 180°. The impedance characteristics of the piezoelectric device according to Comparative Example 2 were determined in the same manner as in Comparative Example 1.

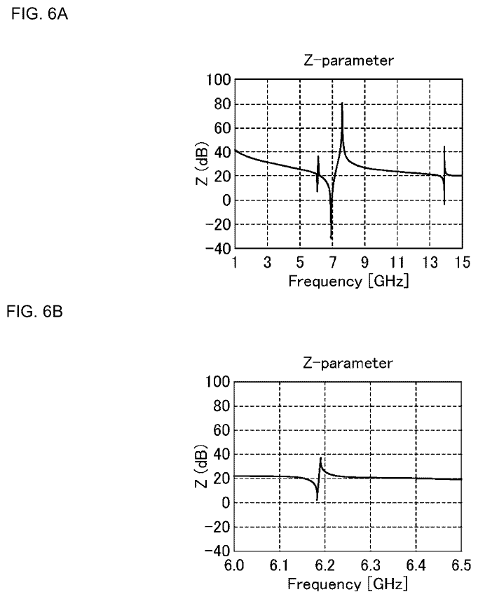

FIG. 6A is a diagram illustrating the resonance characteristics of Comparative Example 2. FIG. 6B is a diagram illustrating an enlarged view of a portion of the band in FIG. 6A. As illustrated in Table 1, FIG. 6A, and FIG. 6B, the piezoelectric device according to Comparative Example 2 had a resonant frequency of 7.0 GHZ, an anti-resonant frequency of 7.6 GHZ, and a spurious wave occurred at 6.2 GHZ.

In Comparative Example 3, as illustrated in Table 1, the impedance characteristics were determined in the same manner as in Comparative Example 2, except that δ was set to 195°.

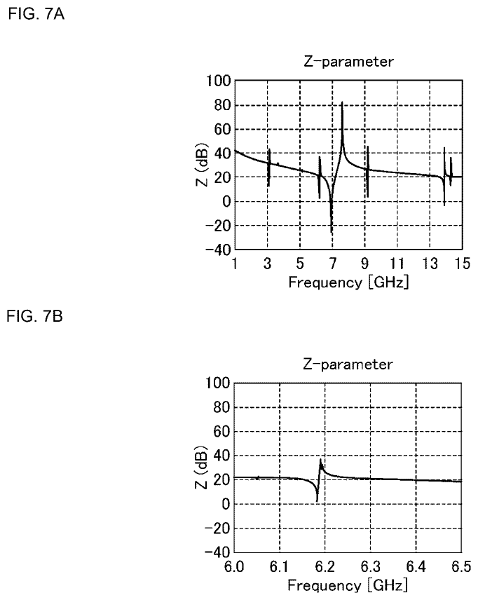

FIG. 7A is a diagram illustrating resonance characteristics according to Comparative Example 3. FIG. 7B is a diagram illustrating an enlarged view of a portion of the band in FIG. 7A. As illustrated in Table 1, FIG. 7A, and FIG. 7B, in the piezoelectric device according to Comparative Example 3, the resonant frequency was 7.0 GHz, the anti-resonant frequency was 7.6 GHZ, and spurious waves were generated at 3.0 GHZ, 6.2 GHZ, and about 9.1 GHZ.

In Comparative Example 4, as illustrated in Table 1, the impedance characteristics were determined in the same manner as in Comparative Example 2, except that δ was set to 180.2°.

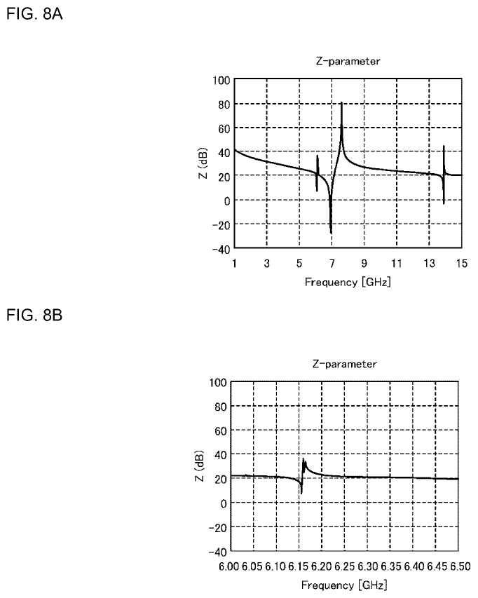

FIG. 8A is a diagram illustrating resonance characteristics according to Comparative Example 4. FIG. 8B is a diagram illustrating an enlarged view of a portion of the band in FIG. 8A. As illustrated in Table 1, FIG. 8A, and FIG. 8B, the piezoelectric device according to Comparative Example 4 had a resonant frequency of 7.0 GHZ, an anti-resonant frequency of 7.6 GHz, and a spurious wave occurred at 6.2 GHZ.

In Comparative Example 5, as illustrated in Table 1, the impedance characteristics were determined in the same manner as in Comparative Example 2, except that δ was set to 180.4°.

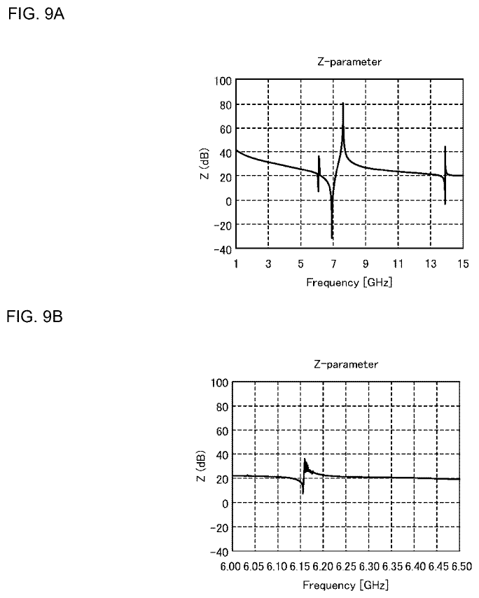

FIG. 9A is a diagram illustrating the resonance characteristics according to Comparative Example 5. FIG. 9B is a diagram illustrating an enlarged view of a portion of the band in FIG. 9A. As illustrated in Table 1, FIG. 9A, and FIG. 9B, the piezoelectric device according to Comparative Example 5 had a resonant frequency of 7.0 GHZ, an anti-resonant frequency of 7.6 GHz, and a spurious wave occurred at 6.2 GHZ.

In Example 1, the piezoelectric layer had a two-layer structure including the first piezoelectric film and the second piezoelectric film. The first piezoelectric film and the second piezoelectric film were X-cut LiTaO₃ single crystals with a thickness of 0.25 μm. The Euler angles of the LiTaO₃ of the first piezoelectric film were (90°, 90°, ψ). The Euler angles of the LiTaO₃ of the second piezoelectric film were (90°, −90°, ψ+δ). In other words, in Example 1, the X1 and X2 directions were opposite directions. As illustrated in Table 1, δ was set to 318°. The impedance characteristics of the piezoelectric device according to Example 1 were determined in the same manner as in Comparative Example 1.

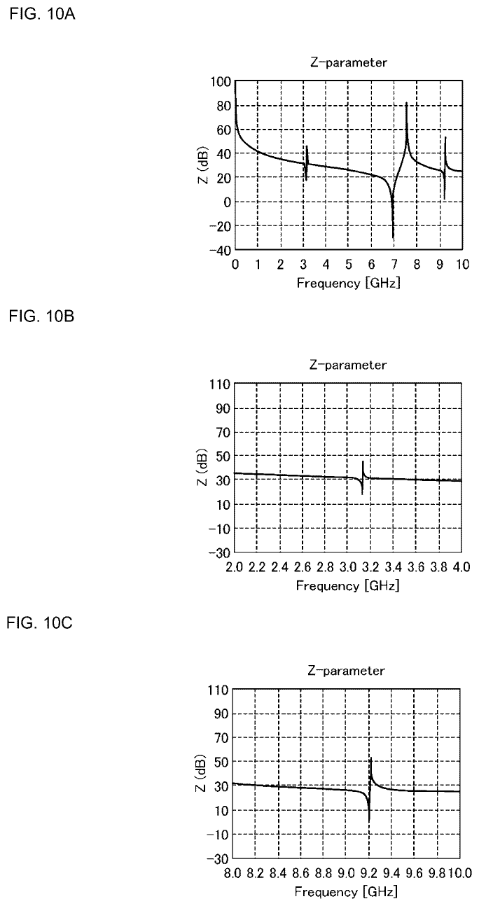

FIG. 10A is a diagram illustrating resonance characteristics according to Example 1. FIGS. 10B and 10C are enlarged views of portions of the band illustrated in FIG. 10A. As illustrated in Table 1, FIGS. 10A, 10B, and 10C, the piezoelectric device according to Example 1 had a resonant frequency of 6.9 GHZ, an anti-resonant frequency of 7.5 GHZ, and spurious waves were generated at 3.1 GHZ and about 9.2 GHZ.

In Example 2, as illustrated in Table 1, the impedance characteristics were determined in the same manner as in Example 1, except that δ was set to 299°.

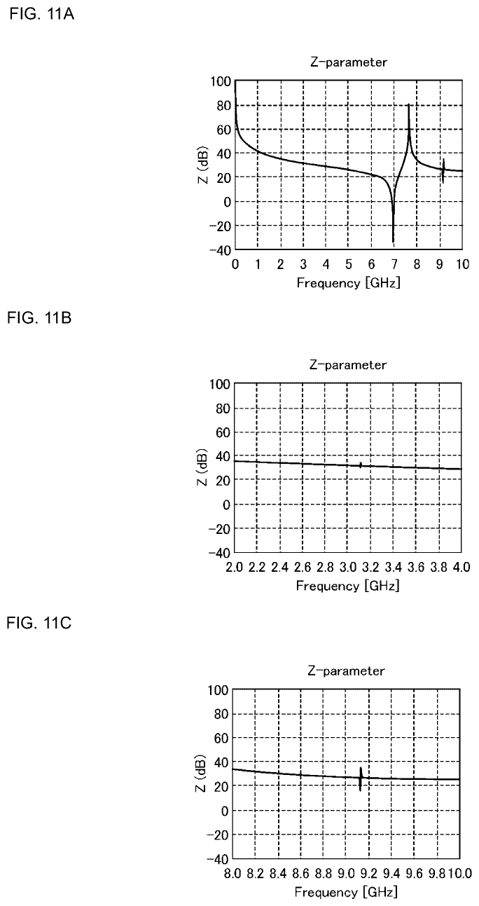

FIG. 11A a diagram illustrating resonance characteristics according to Example 2. FIGS. 11B and 11C are enlarged views of portions of the band illustrated in FIG. 11A. As illustrated in Table 1, FIGS. 11A, 11B, and 11C, the piezoelectric device according to Example 2 had a resonant frequency of 7.0 GHZ, an anti-resonant frequency of 7.6 GHZ, and spurious waves were generated at 3.1 GHZ and about 9.1 GHZ.

In Example 3, as illustrated in Table 1, the impedance characteristics were determined in the same manner as in Example 1, except that δ was set to 280°.

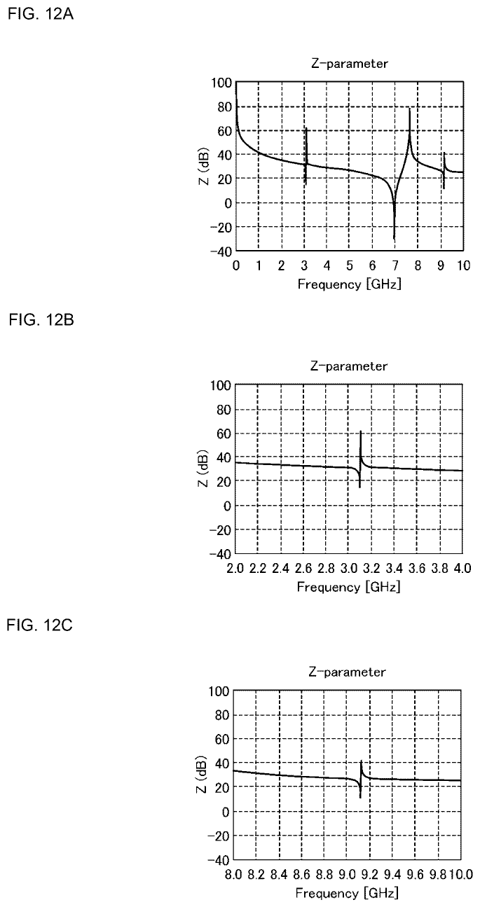

FIG. 12A is a diagram illustrating resonance characteristics according to Example 3. FIGS. 12B and 12C are enlarged views of portions of the band in FIG. 12A. As illustrated in Table 1, FIGS. 12A, 12B, and 12C, in the piezoelectric device according to Example 3, the resonant frequency was 7.0 GHZ, the anti-resonant frequency was 7.6 GHZ, and spurious waves were generated at 3.1 GHZ and about 9.1 GHZ.

In Example 4, as illustrated in Table 1, the impedance characteristics were determined in the same manner as in Example 1, except that δ was set to 301°.

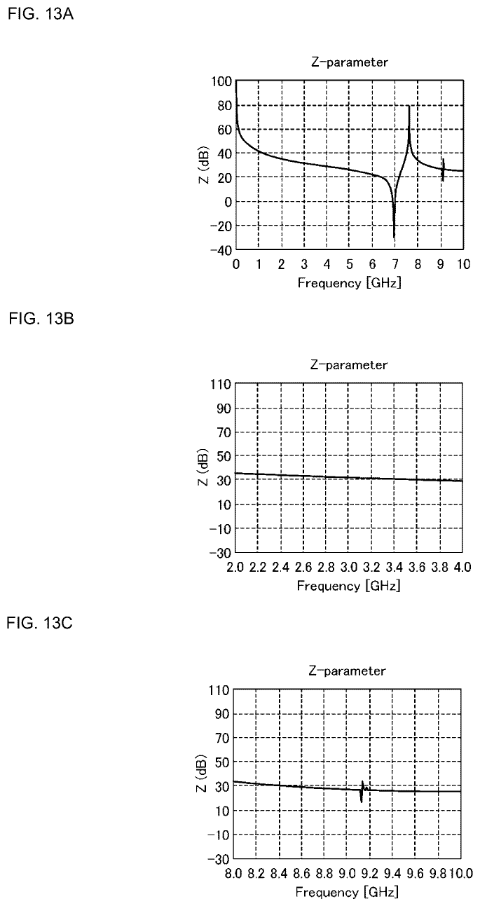

FIG. 13A is a diagram illustrating resonance characteristics according to Example 4. FIGS. 13B and 13C are enlarged views of portions of the band in FIG. 13A. As illustrated in Table 1, FIGS. 13A, 13B, and 13C, the piezoelectric device according to Example 4 had a resonant frequency of 7.0 GHZ, an anti-resonant frequency of 7.6 GHZ, and a spurious wave occurred at 9.1 GHZ.

In Example 5, as illustrated in Table 1, the impedance characteristics were determined in the same manner as in Example 1, except that δ was set to 292°.

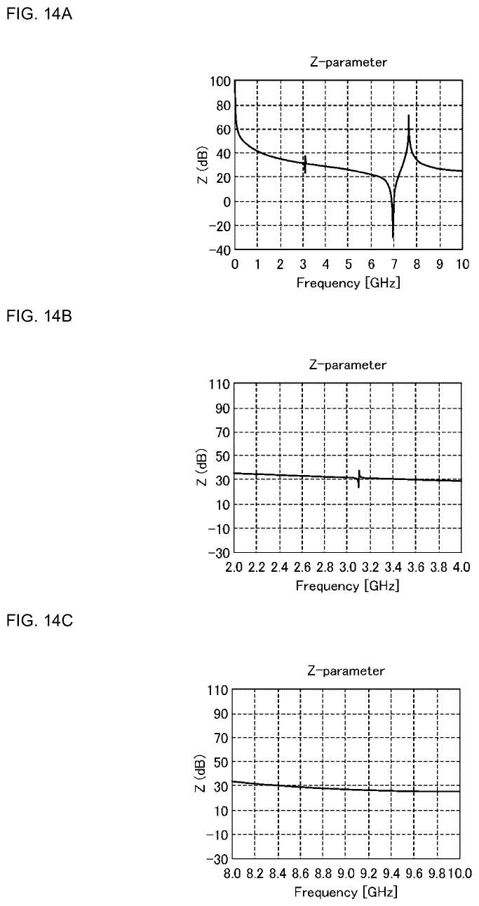

FIG. 14A is a diagram illustrating resonance characteristics according to Example 5. FIGS. 14B and 14C are enlarged views of portions of the band in FIG. 14A. As illustrated in Table 1, FIGS. 14A, 14B, and 14C, the piezoelectric device according to Example 5 had a resonant frequency of 7.0 GHZ, an anti-resonant frequency of 7.6 GHZ, and a spurious wave occurred at 3.1 GHZ.

In Example 6, as illustrated in Table 1, the impedance characteristics were determined in the same manner as in Example 1, except that δ was set to 129°.

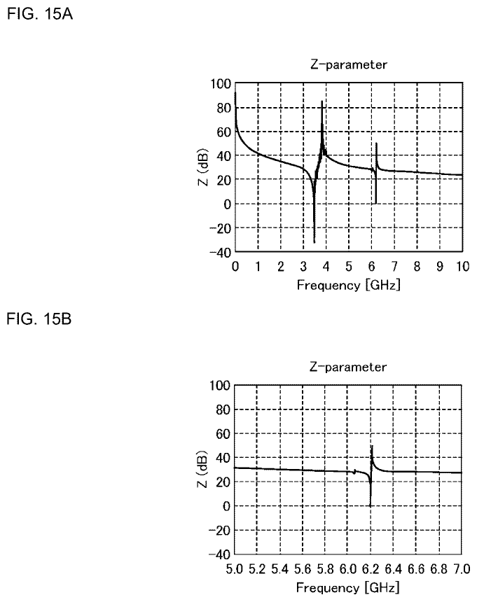

FIG. 15A is a diagram illustrating resonance characteristics according to Example 6. FIG. 15B is a diagram illustrating an enlarged view of a portion of the band in FIG. 15A. As illustrated in Table 1, FIG. 15A, and FIG. 15B, in the piezoelectric device according to Example 6, the resonant frequency was 3.5 GHz, the anti-resonant frequency was 3.9 GHZ, and a spurious wave occurred at 6.2 GHz.

In Example 7, as illustrated in Table 1, the impedance characteristics were determined in the same manner as in Example 1, except that δ was set to 116°.

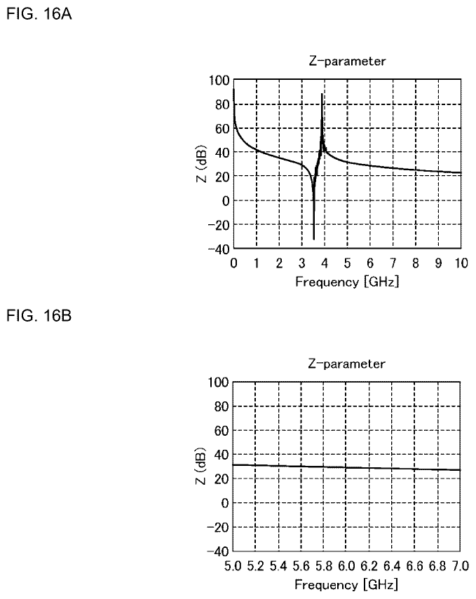

FIG. 16A is a diagram illustrating resonance characteristics according to Example 7. FIG. 16B is a diagram illustrating an enlarged view of a portion of the band in FIG. 16A. As illustrated in Table 1, FIG. 16A, and FIG. 16B, in the piezoelectric device according to Example 7, the resonant frequency was 3.5 GHZ, the anti-resonant frequency was 3.9 GHZ, and no spurious waves were generated.

In Example 8, as illustrated in Table 1, the impedance characteristics were determined in the same manner as in Example 1, except that δ was set to 103°.

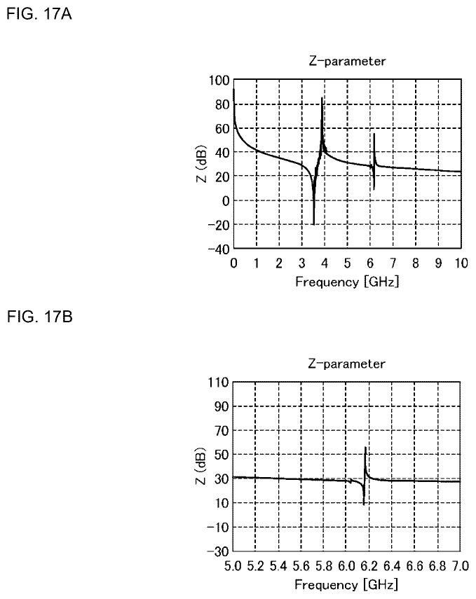

FIG. 17A is a diagram illustrating resonance characteristics according to Example 8. FIG. 17B is a diagram illustrated an enlarged view of a portion of the band in FIG. 17A. As illustrated in Table 1, FIG. 17A, and FIG. 17B, the piezoelectric device according to Example 8 had a resonant frequency of 3.5 GHZ, an anti-resonant frequency of 3.9 GHZ, and a spurious wave occurred at 6.2 GHZ.

In Comparative Example 6, the piezoelectric layer was a single layer including the first piezoelectric film. Here, the first piezoelectric film was an X-cut LiNbO₃ single crystal with a thickness of 0.25 μm. The Euler angles of the LiNbO₃ of the first piezoelectric film were (90°, 90°, ψ). For the piezoelectric device of Comparative Example 6, the impedance characteristics were determined in the same manner as in Comparative Example 1.

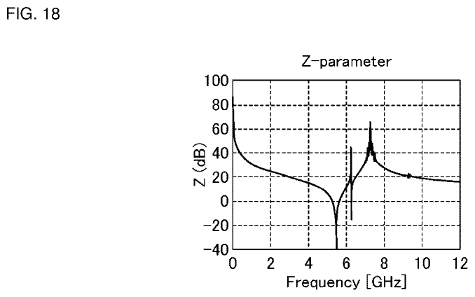

FIG. 18 is a diagram illustrating the resonance characteristics according to Comparative Example 6. As illustrated in Table 1 and FIG. 18, in the piezoelectric device according to Comparative Example 6, the resonant frequency was 5.8 GHz, the anti-resonant frequency was 7.4 GHZ, and a spurious wave occurred at 6.4 GHZ.

In Comparative Example 7, the piezoelectric layer had a two-layer structure including the first piezoelectric film and the second piezoelectric film. The first piezoelectric film and the second piezoelectric film were X-cut LiNbO₃ single crystals with a thickness of 0.25 μm. The Euler angles of the LiNbO₃ of the first piezoelectric film were (90°, 90°, ψ). The Euler angles of the LiNbO₃ in the second piezoelectric film were (90°, 90°, ψ+δ). That is, in Comparative Example 7, the X1 and X2 directions were the same direction. Therefore, ψ+δ in Comparative Example 7 is the angle between the Y2 direction and the X0 direction when viewed in plan view from the Z0 direction, and corresponds to the angle between the Z2 direction and the Y0 direction. As illustrated in Table 1, δ was set to 180°. The impedance characteristics of the piezoelectric device in Comparative Example 7 were determined in the same manner as in Comparative Example 1.

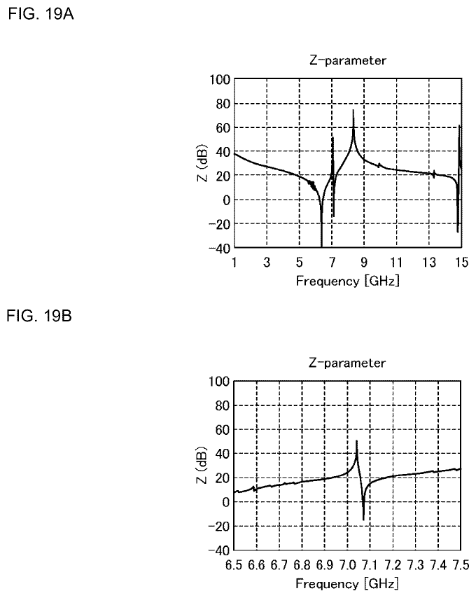

FIG. 19A is a diagram illustrating resonance characteristics according to Comparative Example 7. FIG. 19B is a diagram illustrating an enlarged view of a portion of the band in FIG. 19A. As illustrated in Table 1, FIG. 19A, and FIG. 19B, the piezoelectric device according to Comparative Example 7 had a resonant frequency of 6.3 GHZ, an anti-resonant frequency of 8.2 GHz, and a spurious wave occurred at 7.1 GHZ.

In Comparative Example 8, as illustrated in Table 1, the impedance characteristics were determined in the same manner as in Comparative Example 7, except that δ was set to 195°.

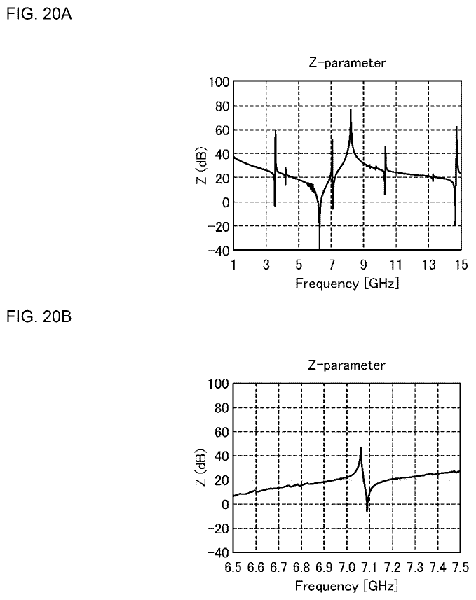

FIG. 20A is a diagram illustrating resonance characteristics according to Comparative Example 8. FIG. 20B is a diagram illustrating an enlarged view of a portion of the band in FIG. 20A. As illustrated in Table 1, FIG. 20A, and FIG. 20B, the piezoelectric device according to Comparative Example 8 had a resonant frequency of 6.3 GHZ, an anti-resonant frequency of 8.2 GHz, and spurious waves occurred at 3.6 GHz, 7.1 GHZ, and 10.3 GHZ.

In Comparative Example 9, as illustrated in Table 1, the impedance characteristics were determined in the same manner as in Comparative Example 7, except that δ was set to 180.2°.

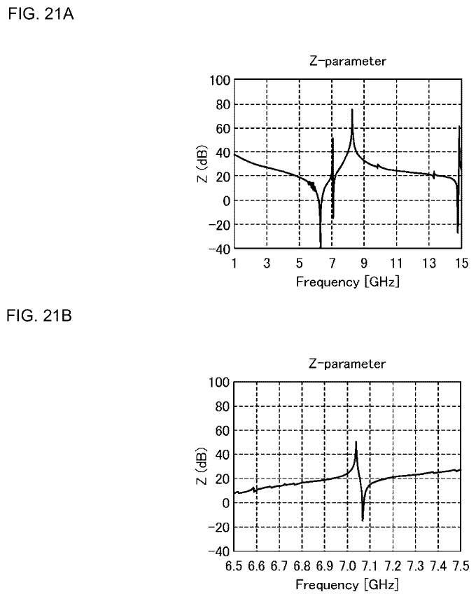

FIG. 21A is a diagram illustrating resonance characteristics according to Comparative Example 9. FIG. 21B is a diagram showing an enlarged view of a portion of the band in FIG. 21A. As illustrated in Table 1, FIG. 21A, and FIG. 21B, the piezoelectric device according to Comparative Example 9 had a resonant frequency of 6.3 GHZ, an anti-resonant frequency of 8.2 GHz, and a spurious wave occurred at 7.1 GHZ.

In Comparative Example 10, as illustrated in Table 1, the impedance characteristics were determined in the same manner as in Comparative Example 7, except that δ was set to 180.4°.

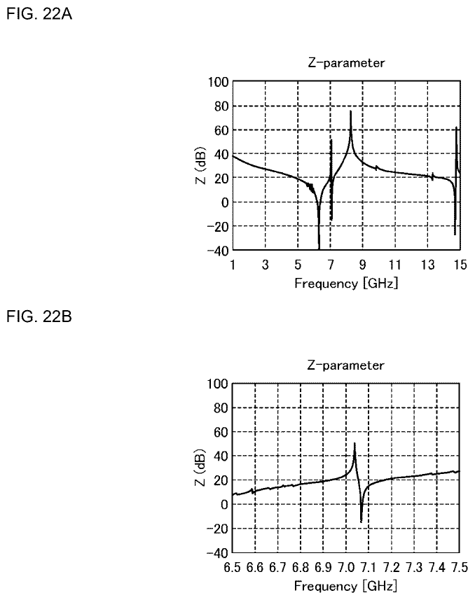

FIG. 22A is a diagram illustrating resonance characteristics according to Comparative Example 10. FIG. 22B is an enlarged view of a portion of the band in FIG. 22A. As illustrated in Table 1, FIG. 22A, and FIG. 22B, the piezoelectric device according to Comparative Example 10 had a resonant frequency of 6.3 GHZ, an anti-resonant frequency of 8.2 GHZ, and a spurious wave occurred at 7.1 GHZ.

In Example 9, the piezoelectric layer had a two-layer structure including the first piezoelectric film and the second piezoelectric film. The first piezoelectric film and the second piezoelectric film were X-cut LiNbO₃ single crystals with a thickness of 0.25 μm. The Euler angles of the LiNbO₃ of the first piezoelectric film were (90°, 90°, v). The Euler angles of the LiNbO₃ of the second piezoelectric film were (90°, −90°, ψ+δ). In other words, in Example 9, the X1 and X2 directions were opposite directions. As illustrated in Table 1, δ was set to 318°. The impedance characteristics of the piezoelectric device in Example 9 were determined in the same manner as in Comparative Example 1.

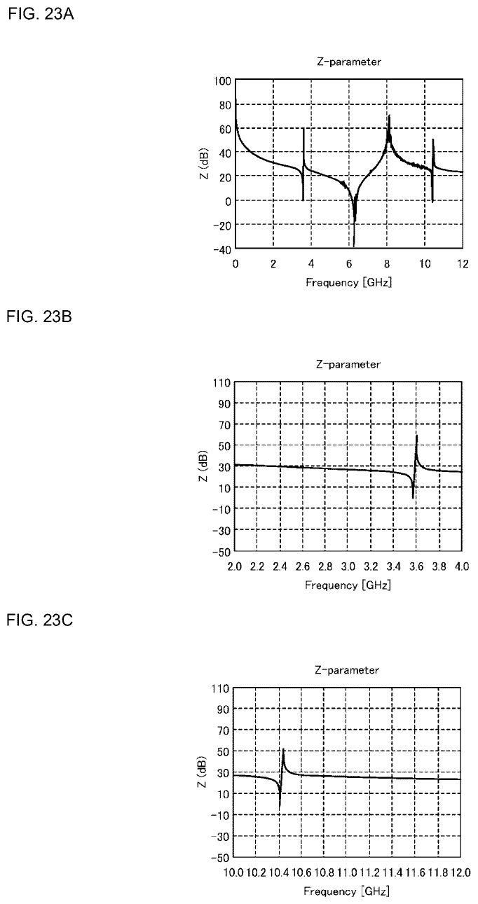

FIG. 23A is a diagram illustrating resonance characteristics according to Example 9. FIG. 23B and FIG. 23C are enlarged views of portions of the band in FIG. 23A. As illustrated in Table 1, FIG. 23A, FIG. 23B, and FIG. 23C, in the piezoelectric device according to Example 9, the resonant frequency was 6.4 GHZ, the anti-resonant frequency was 8.2 GHz, and spurious waves occurred at 3.6 GHZ and 10.4 GHZ.

In Example 10, as illustrated in Table 1, the impedance characteristics were determined in the same manner as in Example 9, except that δ was set to 301°.

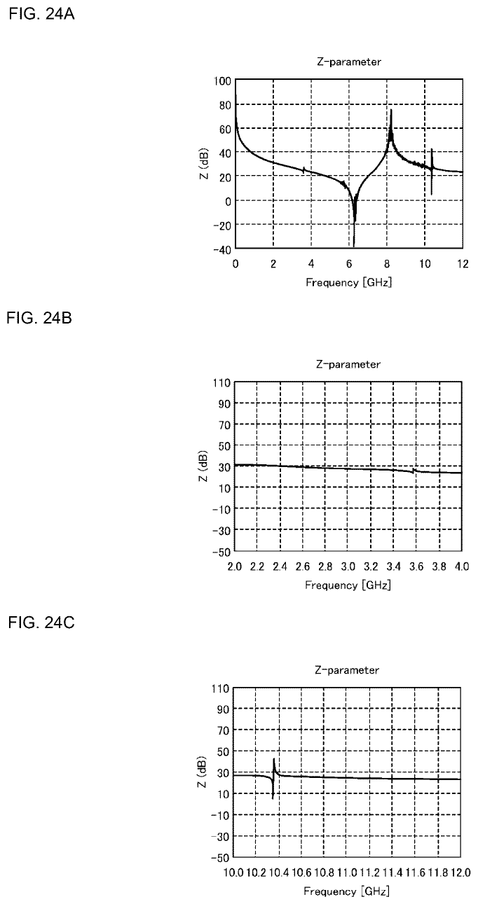

FIG. 24A is a illustrating diagram resonance characteristics according to Example 10. FIGS. 24B and 24C are enlarged views of portions of the band in FIG. 24A. As illustrated in Table 1, FIGS. 24A, 24B, and 24C, the piezoelectric device according to Example 10 had a resonant frequency of 6.4 GHZ, an anti-resonant frequency of 8.2 GHZ, and spurious waves occurred at 3.6 GHZ and 10.4 GHZ.

In Example 11, as illustrated in Table 1, the impedance characteristics were determined in the same manner as in Example 9, except that δ was set to 280°.

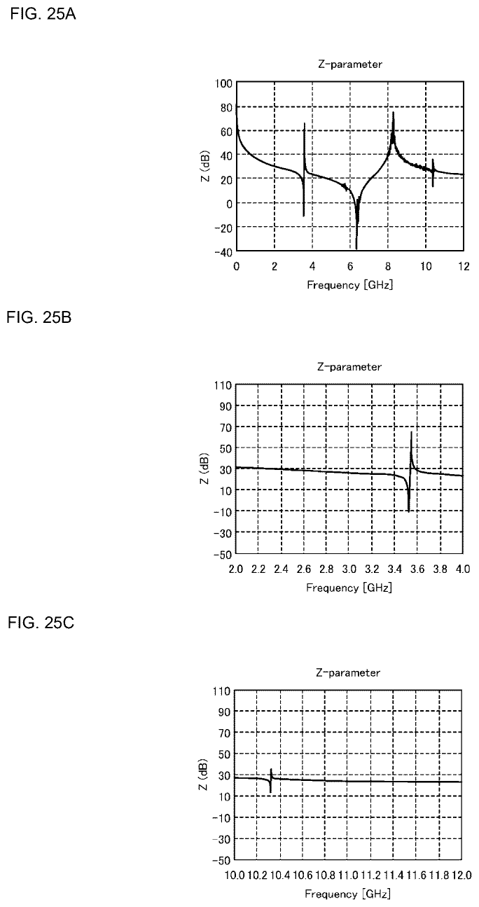

FIG. 25A is a diagram illustrating resonance characteristics according to Example 11. FIGS. 25B and 25C are enlarged views of portions of the band in FIG. 25A. As illustrated in Table 1, FIGS. 25A, 25B, and 25C, the piezoelectric device according to Example 11 had a resonant frequency of 6.4 GHZ, an anti-resonant frequency of 8.2 GHZ, and spurious waves occurred at 3.6 GHz and 10.4 GHz.

In Example 12, as illustrated in Table 1, the impedance characteristics were determined in the same manner as in Example 9, except that δ was set to 299°.

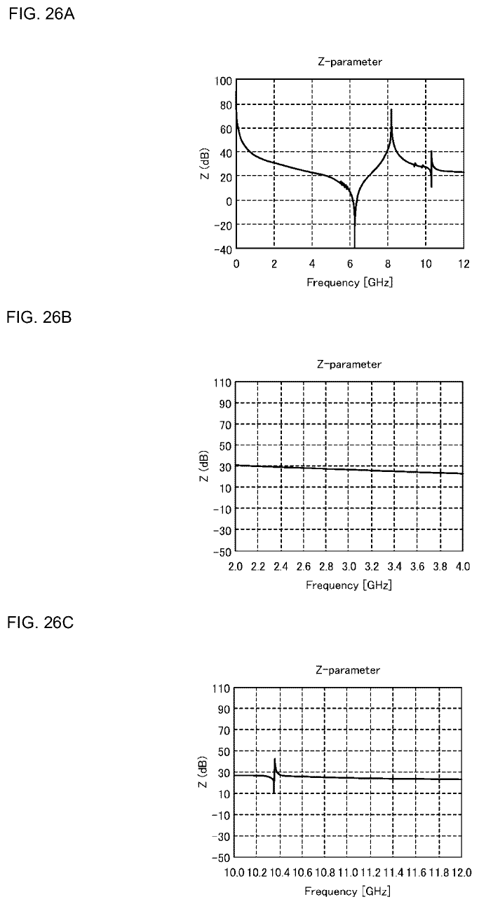

FIG. 26A diagram is a illustrating resonance characteristics according to Example 12. FIGS. 26B and 26C are enlarged views of portions of the band in FIG. 26A. As illustrated in Table 1, FIGS. 26A, 26B, and 26C, the piezoelectric device according to Example 12 had a resonant frequency of 6.4 GHZ, an anti-resonant frequency of 8.2 GHZ, and a spurious wave occurred at 10.4 GHZ.

In Example 13, as illustrated in Table 1, the impedance characteristics were determined in the same manner as in Example 9, except that δ was set to 289°.

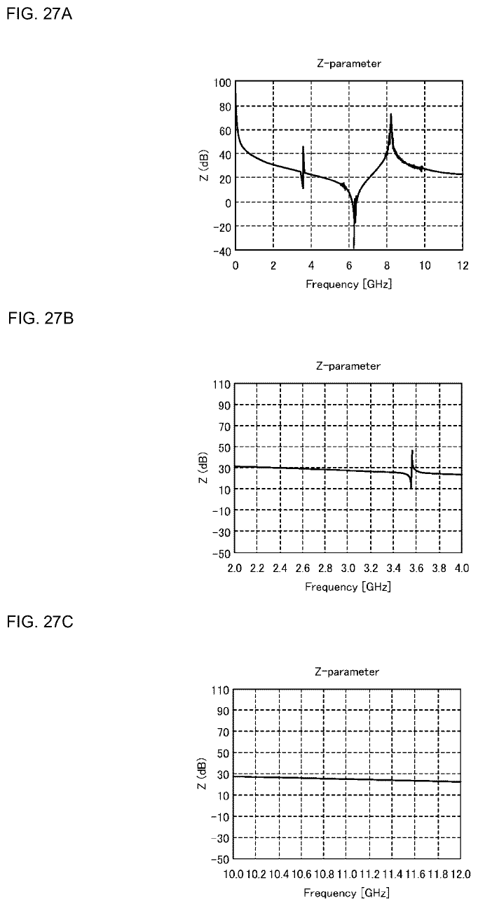

FIG. 27A is a diagram illustrating resonance characteristics according to Example 13. FIG. 27B and FIG. 27C are enlarged views of portions of the band in FIG. 27A. As illustrated in Table 1, FIG. 27A, FIG. 27B, and FIG. 27C, in the piezoelectric device according to Example 13, the resonant frequency was 6.4 GHz, the anti-resonant frequency was 8.2 GHZ, and a spurious wave occurred at 3.6 GHz.

In Example 14, as illustrated in Table 1, the impedance characteristics were determined in the same manner as in Example 9, except that δ was set to 127°.

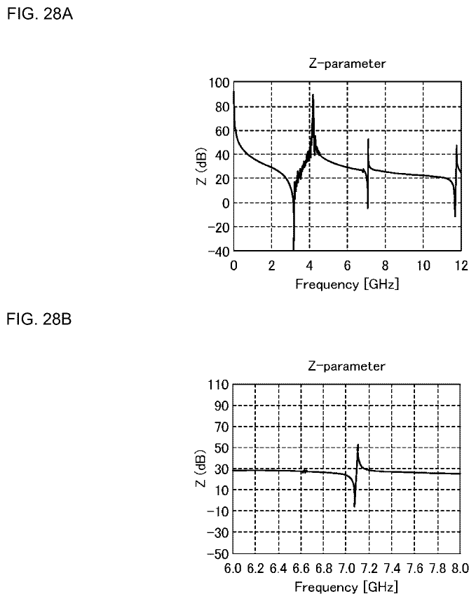

FIG. 28A is a diagram illustrating resonance characteristics according to Example 14. FIG. 28B is an enlarged view of a portion of the band in FIG. 28A. As illustrated in Table 1, FIG. 28A, and FIG. 28B, in the piezoelectric device according to Example 14, the resonant frequency was 3.2 GHZ, the anti-resonant frequency was 4.2 GHZ, and a spurious wave occurred at 7.1 GHZ.

In Example 15, as illustrated in Table 1, the impedance characteristics were determined in the same manner as in Example 9, except that δ was set to 114°.

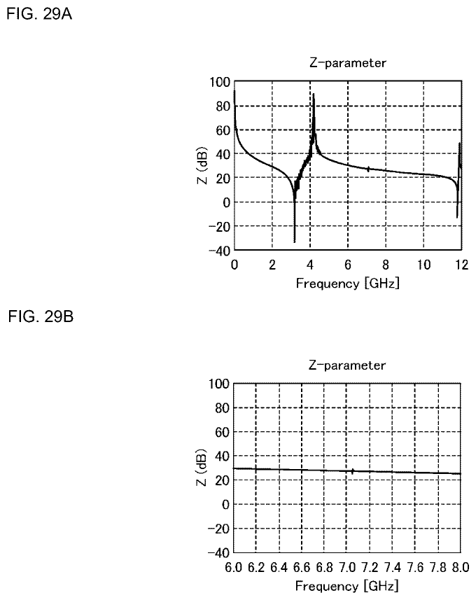

FIG. 29A is a diagram illustrating resonance characteristics according to Example 15. FIG. 29B is an enlarged view of a portion of the band in FIG. 29A. As illustrated in Table 1, FIG. 29A, and FIG. 29B, the piezoelectric device according to Example 15 had a resonant frequency of 3.2 GHZ, an anti-resonant frequency of 4.2 GHZ, and a spurious wave slightly occurred at 7.1 GHZ.

In Example 16, as illustrated in Table 1, the impedance characteristics were determined in the same manner as in Example 9, except that δ was set to 101°.

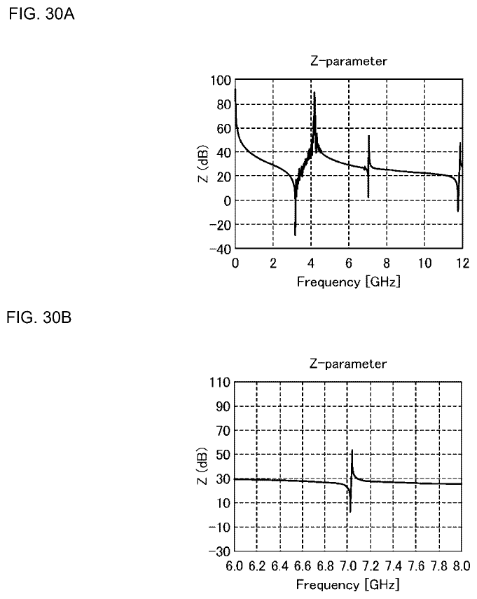

FIG. 30A is a diagram illustrating resonance characteristics according to Example 16. FIG. 30B is an enlarged view of a portion of the band in FIG. 30A. As illustrated in Table 1, FIG. 30A, and FIG. 30B, in the piezoelectric device according to Example 16, the resonant frequency was 3.2 GHZ, the anti-resonant frequency was 4.2 GHZ, and a spurious wave occurred at 7.1 GHZ.

When the first piezoelectric film and the second piezoelectric film are X-cut LiTaO₃ single crystals, it can be seen that in Examples 1 to 5, where δ is 280° or more and 318° or less, the frequency of the spurious wave is about half that in Comparative Examples 1 to 5, and the spurious wave is farther away from the resonance point. This is thought to be because in Examples 1 to 5, the shear direction of a main wave of the first piezoelectric film and the shear direction of a main wave of the second piezoelectric film are opposite directions, and the shear direction of a spurious wave of the first piezoelectric film and the shear direction of a spurious wave of the second piezoelectric film are the same direction.

When the first piezoelectric film and the second piezoelectric film are X-cut LiTaO₃ single crystals, it can be seen that in Example 4, where δ is 298° or more and 304° or less, the spurious wave on the low frequency side relative to the resonant frequency can be suppressed more effectively than in Examples 1 and 3.

When the first piezoelectric film and the second piezoelectric film are X-cut LiTaO₃ single crystals, it can be seen that in Example 5, where δ is 289° or more and 295° or less, the spurious wave on the high frequency side relative to the anti-resonant frequency can be suppressed more effectively than in Examples 1 to 3.

When the first piezoelectric film and the second piezoelectric film were X-cut LiTaO₃ single crystals, it can be seen that in Examples 6 to 8, in which δ was 103° or more and 129° or less, the resonant frequency was about half that in Comparative Examples 1 to 5, and the resonance point was farther away from a spurious wave. This is thought to be because in Examples 6 to 8, the shear direction of a main wave of the first piezoelectric film and the shear direction of a main wave of the second piezoelectric film were the same direction, and the shear direction of a spurious wave of the first piezoelectric film and the shear direction of a spurious wave of the second piezoelectric film were opposite directions.

When the first piezoelectric film and the second piezoelectric film were X-cut LiTaO₃ single crystals, it can be seen that in Example 7, where δ is 113° or more and 119° or less, the spurious wave on the high frequency side relative to the anti-resonant frequency can be suppressed more effectively than in Examples 6 and 8.

When the first and second piezoelectric films were X-cut LiNbO₃ single crystals, in Examples 9 to 13, in which δ was 280° or more and 318° or less, it can be seen that the frequency of the spurious wave was about half that in Comparative Examples 6 to 10, and the spurious wave was farther away from the resonance point. This is thought to be because in Examples 9 to 13, the shear direction of a main wave of the first piezoelectric film and the shear direction of a main wave of the second piezoelectric film were opposite directions, and the shear direction of a spurious wave of the first piezoelectric film and the shear direction of a spurious wave of the second piezoelectric film were the same direction.

When the first piezoelectric film and the second piezoelectric film were X-cut LiNbO₃ single crystals, it can be seen that in Example 12, in which δ is 296° or more and 302° or less, the spurious wave on the low frequency side relative to the resonant frequency can be suppressed more effectively than in Examples 9 and 11.

When the first piezoelectric and the second piezoelectric film were composed of X-cut LiNbO₃ single crystals, it was found that in Example 13, in which δ was 286° or more and 292° or less, the spurious wave on the high frequency side relative to the anti-resonant frequency was suppressed more effectively than in Examples 9 to 11.

When the first piezoelectric film and the second piezoelectric film were X-cut LiNbO₃ single crystals, it was found that in Examples 14 to 16, in which δ was 101° or more and 127° or less, the resonant frequency was about half that in Comparative Examples 6 to 10, and the resonance point was farther away from the spurious wave. This is thought to be because in Examples 14 to 16, the shear direction of a main wave of the first piezoelectric film and the shear direction of a main wave of the second piezoelectric film were the same direction, and the shear direction of a spurious wave of the first piezoelectric film and the shear direction of a spurious wave of the second piezoelectric film were opposite directions.

When the first and second piezoelectric films are X-cut LiNbO₃ single crystals, it can be seen that in Example 15, where δ is 111° or more and 117° or less, the spurious wave on the high frequency side relative to the anti-resonant frequency can be suppressed more effectively than in Examples 14 and 16.

The above-described example embodiments are intended to facilitate understanding of the present invention and are not intended to limit the present invention. The present invention may be modified or improved without departing from the spirit and scope of the present invention, and equivalents thereof are also included in the present invention.

For example, when the direction of a crystal axis is expressed as Euler angles, the direction of that crystal axis includes directions that, although expressed differently, correspond to the same orientation as the x′″-axis direction, y′″-axis direction, and z′″-axis direction relative to the x-axis direction. For example, when 1, m, and n are any integers, a crystal orientation with Euler angles (x+360°×1, β+360°×m, γ+360°×n) is the same orientation as a crystal orientation with Euler angles (α, β, γ). Furthermore, for example, a crystal orientation with Euler angles (90°, −90°, γ) is the same orientation as a crystal orientation with Euler angles (−90°, 90°, γ+180°). Here, α, β, and γ are arbitrary.

For example, when the direction of a crystal axis is expressed as Euler angles, the direction of that crystal axis includes directions that, although expressed differently, correspond to the same orientation as the x′″, y′″, and z′″-axes relative to the a-axis direction of the crystal. The LiTaO₃ and LiNbO₃ crystals according to the present disclosure are trigonal. That is, the LiTaO₃ and LiNbO₃ crystals according to the present disclosure have three a-axis directions. Here, the angle formed by each a-axis direction from the c-axis direction in plan view is about 120°, for example. Therefore, for example, the crystal orientation with Euler angles (90°, 90°, γ) is the same as the crystal orientation with Euler angles (210°, 90°, γ), and also, for example, when k is an arbitrary integer, the crystal orientation with Euler angles (α+120°×k, 90°, γ) is the same as the crystal orientation with Euler angles (α, 90°, γ), and the crystal orientation with Euler angles (α+120°×k, −90°, γ) is the same as the crystal orientation with Euler angles (α, −90°, γ). Here, α, β, and γ are arbitrary.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a support including a support substrate;
a piezoelectric layer having a thickness in a first direction and provided on a main surface of the support; and
a functional electrode provided on a main surface of the piezoelectric layer; wherein
the piezoelectric layer includes a first piezoelectric film and a second piezoelectric film stacked on the first piezoelectric film;
a polarization direction of the first piezoelectric film and a polarization direction of the second piezoelectric film are directions that intersect each other; and
a displacement direction of a main wave of the first piezoelectric film and a displacement direction of a main wave of the second piezoelectric film are directions that are parallel to each other.

2. The piezoelectric device according to claim 1, wherein the first piezoelectric film and the second piezoelectric film include lithium tantalate.

3. The piezoelectric device according to claim 2, wherein the first piezoelectric film and the second piezoelectric film include X-cut lithium tantalate single crystal.

4. The piezoelectric device according to claim 3, wherein an a-axis direction of the lithium tantalate crystal of the first piezoelectric film and an a-axis direction of the lithium tantalate crystal of the second piezoelectric film are opposite directions.

5. The piezoelectric device according to claim 4, wherein when Euler angles of the lithium tantalate of the first piezoelectric film are (φ₁, θ₁, ψ), Euler angles of the lithium tantalate of the second piezoelectric film are expressed as (φ₂, θ₂, ψ+δ):
the φ1 is greater than or equal to about 87° and less than or equal to about 93°;
the θ₁ is greater than or equal to about 87° and less than or equal to about 93°;
the φ₂ is greater than or equal to about 87° and less than or equal to about 93°;
the θ₂ is greater than or equal to about −93° and less than or equal to about −87°; and
the δ is greater than or equal to about 280° and less than or equal to about 318°.

6. The piezoelectric device according to claim 5, wherein the δ is equal to or greater than about 298° and equal to or less than about 304°.

7. The piezoelectric device according to claim 5, wherein the δ is greater than or equal to about 289° and less than or equal to about 295°.

8. The piezoelectric device according to claim 4, wherein when Euler angles of the lithium tantalate of the first piezoelectric film are (φ₁, θ₁, ψ), Euler angles of the lithium tantalate of the second piezoelectric film are expressed as (φ₂, θ₂, ψ+δ):
the φ₁ is greater than or equal to about 87° and less than or equal to about 93°;
the θ₁ is greater than or equal to about 87° and less than or equal to about 93°;
the φ2 is greater than or equal to about 87° and less than or equal to about 93°;
the θ₂ is greater than or equal to about −93° and less than or equal to about −87°; and
the δ is greater than or equal to about 103° and less than or equal to about 129°.

9. The piezoelectric device according to claim 8, wherein the 8 is greater than or equal to about 113° and less than or equal to about 119°.

10. The piezoelectric device according to claim 1, wherein the first piezoelectric film and the second piezoelectric film include lithium niobate.

11. The piezoelectric device according to claim 10, wherein the first piezoelectric film and the second piezoelectric film include X-cut lithium niobate single crystal.

12. The piezoelectric device according to claim 11, wherein an a-axis direction of the lithium niobate crystal of the first piezoelectric film and an a-axis direction of the lithium niobate crystal of the second piezoelectric film are opposite directions.

13. The piezoelectric device according to claim 12, wherein when Euler angles of the lithium niobate of the first piezoelectric film are (φ₁, θ₁, ψ), Euler angles of the lithium niobate of the second piezoelectric film are expressed as (φ₂, θ₂, ψ+δ):
the φ₁ is greater than or equal to about 87° and less than or equal to about 93°;
the θ₁ is greater than or equal to about 87° and less than or equal to about 93°;
the φ₂ is greater than or equal to about 87° and less than or equal to about 93°;
the θ₂ is greater than or equal to about −93° and less than or equal to about −87°; and
the δ is greater than or equal to about 280° and less than or equal to about 318°.

14. The piezoelectric device according to claim 13, wherein the δ is greater than or equal to about 296° and less than or equal to about 302°.

15. The piezoelectric device according to claim 13, wherein the δ is greater than or equal to about 286° and less than or equal to about 292°.

16. The piezoelectric device according to claim 12, wherein when Euler angles of the lithium niobate of the first piezoelectric film are (φ₁, θ₁, ψ), Euler angles of the lithium niobate of the second piezoelectric film are expressed as (φ2, θ₂, ψ+δ):
the φ₁ is greater than or equal to about 87° and less than or equal to about 93°;
the θ₁ is greater than or equal to about 87° and less than or equal to about 93°;
the φ2 is greater than or equal to about 87° and less than or equal to about 93°;
the θ₂ is greater than or equal to about −93° and less than or equal to about −87°; and
the δ is greater than or equal to about 101° and less than or equal to about 127°.

17. The piezoelectric device according to claim 16, wherein the δ is greater than or equal to about 111° and less than or equal to about 117°.

18. The piezoelectric device according to claim 1, wherein the support further includes an intermediate layer on a side of the support substrate where the piezoelectric layer is located.

19. A piezoelectric device comprising:
a support including a support substrate;
a piezoelectric layer having a thickness in a first direction and provided on a main surface of the support; and
a functional electrode provided on a main surface of the piezoelectric layer; wherein
the piezoelectric layer includes a first piezoelectric film and a second piezoelectric film stacked on the first piezoelectric film;
a polarization direction of the first piezoelectric film and a polarization direction of the second piezoelectric film are directions other than opposite directions;
a displacement direction of a main wave of the first piezoelectric film and a displacement direction of a main wave of the second piezoelectric film are opposite directions; and
a displacement direction of a spurious wave of the first piezoelectric film and a displacement direction of a spurious wave of the second piezoelectric film are identical directions.

20. A piezoelectric device comprising:
a support including a support substrate;
a piezoelectric layer having a thickness in a first direction and provided on a main surface of the support; and
a functional electrode provided on a main surface of the piezoelectric layer; wherein
the piezoelectric layer includes a first piezoelectric film and a second piezoelectric film stacked on the first piezoelectric film;
a polarization direction of the first piezoelectric film and a polarization direction of the second piezoelectric film are directions other than opposite directions;
a displacement direction of a main wave of the first piezoelectric film and a displacement direction of a main wave of the second piezoelectric film are identical directions; and
a displacement direction of a spurious wave of the first piezoelectric film and a displacement direction of a spurious wave of the second piezoelectric film are opposite directions.

21. A piezoelectric device comprising:
a support including a support substrate;
a piezoelectric layer having a thickness in a first direction and provided on a main surface of the support; and
a functional electrode provided on a main surface of the piezoelectric layer; wherein
the piezoelectric layer includes a first piezoelectric film and a second piezoelectric film stacked on the first piezoelectric film; and
an a-axis direction of a lithium tantalate crystal of the first piezoelectric film and an a-axis direction of a lithium tantalate crystal of the second piezoelectric film are opposite directions.

22. A piezoelectric device comprising:
a support including a support substrate;
a piezoelectric layer having a thickness in a first direction and provided on a main surface of the support; and
a functional electrode provided on a main surface of the piezoelectric layer; wherein
the piezoelectric layer includes a first piezoelectric film and a second piezoelectric film stacked on the first piezoelectric film; and
an a-axis direction of lithium niobate crystal of the first piezoelectric film and an a-axis direction of lithium niobate crystal of the second piezoelectric film are opposite directions.

23. A filter comprising:
the piezoelectric device according to claim 1.
